(19) United States
(12) Patent Application Publication
(10) Pub. No.: US 2025/0120076 A1
(43) Pub. Date: Apr. 10, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Moonkang Choi, Suwon-si (KR); Jongho Woo, Suwon-si (KR); Sangwoo Han, Suwon-si (KR)

(21) Appl. No.: 18/653,571

(22) Filed: May 2, 2024

(30) Foreign Application Priority Data
Oct. 4, 2023 (KR) 10-2023-0131991

(51) Int. Cl. H10B 41/27; H01L 25/065; H10B 41/10; H10B 41/35; H10B 41/41; H10B 43/10; H10B 43/27; H10B 43/35; H10B 43/40; H10B 80/00

(52) U.S. Cl. CPC H10B 41/27; H01L 25/0652; H10B 41/10; H10B 41/35; H10B 41/41; H10B 43/10; H10B 43/27; H10B 43/35; H10B 43/40; H10B 80/00; H01L 2225/06506

(57) ABSTRACT

A semiconductor device and an electronic system including the device are presented. The device includes a substrate, a stacked structure with a plurality of gate electrodes on the substrate and spaced apart from each other, a first channel structure, and a second channel structure. The first channel structure includes a first channel layer extending through the stacked structure and a first ferroelectric layer positioned between the first channel layer and the stacked structure. The second channel structure includes a second channel layer with a first portion extending through the selection gate electrode, a second portion extending through the insulating pattern to contact an upper surface of the first channel layer, and a third portion protruding from a lower surface of the second portion and contacting an outer surface of the first channel layer.

### CROSS-REFERENCE TO RELATED APPLICATION

This application claims priority to and the benefit of Korean Patent Application No. 10-2023-0131991, filed in the Korean Intellectual Property Office on Oct. 4, 2023, the entire contents of which are incorporated herein by reference.

### TECHNICAL FIELD

The present disclosure relates to a semiconductor device and an electronic system including the same.

### BACKGROUND

A semiconductor is a material belonging to an intermediate region between a conductor and an insulator and refers to a material that conducts electricity under a predetermined condition. Various semiconductor devices can be manufactured by using such a semiconductor material, and for example, a memory device and the like can be manufactured. Memory devices may be classified into volatile memory devices and non-volatile memory devices. In the case of a non-volatile memory device, contents may not be deleted even if power is cut off and may be used in various electronic devices such as mobile phones, digital cameras, and PCs.

In accordance with recent trend of increasing storage capacity, a degree of integration of non-volatile memory devices is required to be improved. The degree of integration of memory devices two-dimensionally arranged on a plane may be limited.

### SUMMARY

This disclosure describes implementations which provide a semiconductor device and an electronic system including the same, capable of improving reliability.

An implementation of the present disclosure provides a semiconductor device including: a substrate; a stacked structure configured to include a plurality of gate electrodes stacked on the substrate and spaced apart from each other; a first channel structure configured to include a first channel layer extending through the stacked structure and extending along a direction, and a first ferroelectric layer positioned between the first channel layer and the stacked structure; an insulating pattern positioned on the stacked structure; a selection gate electrode positioned on the insulating pattern; and a second channel structure connected to the first channel structure through the selection gate electrode and the insulating pattern and configured to include a second channel layer extending along the direction, wherein the second channel layer includes: a first portion configured to extend through the selection gate electrode; a second portion configured to extend through the insulating pattern to contact an upper surface of the first channel layer; and a third portion configured to protrude from a lower surface of the second portion and to contact an outer surface of the first channel layer.

An implementation of the present disclosure provides a semiconductor device including: a substrate; a stacked structure configured to include a plurality of gate electrodes stacked on the substrate and spaced apart from each other; a first channel structure configured to include a first channel layer extending through the stacked structure and extending along a direction, and a first ferroelectric layer positioned between the first channel layer and the stacked structure; an insulating pattern positioned on the stacked structure; a selection gate electrode positioned on the insulating pattern; and a second channel layer configured to overlap at least a portion of the first channel structure in the direction, and to include a second channel layer connected to the first channel structure through the selection gate electrode and the insulating pattern, and a second ferroelectric layer positioned between the second channel layer and the selection gate electrode, wherein the second channel layer includes: a first portion configured to extend through the selection gate electrode; a second portion configured to extend through the insulating pattern to contact an upper surface of the first channel layer; and a third portion positioned between the first ferroelectric layer and the second portion and to contact a side surface of the first channel layer.

An implementation of the present disclosure provides an electronic system including a semiconductor device, including: a main substrate; a semiconductor device on the main substrate; and a controller electrically connected to the semiconductor device on the main substrate, wherein the semiconductor device includes: a peripheral circuit region; a cell region configured to include an input/output connection wire electrically connected to the peripheral circuit region; and an input/output pad electrically connected to the input/output connection wire extending into the cell region, wherein the cell region includes: a substrate; a stacked structure configured to include a plurality of gate electrodes stacked on the substrate and spaced apart from each other; a first channel structure configured to include a first channel layer extending through the stacked structure and extending along a direction, and a first ferroelectric layer positioned between the first channel layer and the stacked structure; a selection gate electrode positioned on the insulating pattern; and a second channel structure connected to the first channel structure through the selection gate electrode and the insulating pattern and configured to include a second channel layer extending along the direction, wherein the second channel layer includes: a first portion configured to extend through the selection gate electrode; a second portion configured to extend through the insulating pattern to contact an upper surface of the first channel layer; and a third portion configured to protrude from a lower surface of the second portion and to contact a side surface of the first channel layer.

Semiconductor devices according to implementations may stably connect the first channel structure and the second channel structure by increasing the contact area between the first channel layer and the second channel layer. Accordingly, the reliability of the semiconductor device may be improved.

### BRIEF DESCRIPTION OF THE DRAWINGS

FIG. 1 illustrates a schematic top plan view of an example semiconductor device.

FIG. 2 illustrates an enlarged view of a region A of FIG. 1.

FIG. 3 illustrates a cross-sectional view taken along a line I-I′ of FIG. 1.

FIG. 4 illustrates an enlarged cross-sectional view of a region B1 of FIG. 3.

FIG. 5 illustrates a top plan view schematically showing a channel structure of an example semiconductor device.

FIG. 6 to FIG. 9 illustrate cross-sectional views corresponding to a region B1 in FIG. 3, showing several example semiconductor devices.

FIG. 10 and FIG. 11 illustrate cross-sectional views showing example semiconductor devices.

FIG. 12 to FIG. 15 illustrate cross-sectional views showing an example manufacturing method for a semiconductor device.

FIG. 16 to FIG. 24 illustrate cross-sectional views corresponding to a region B2 in FIG. 15, showing an example manufacturing method for a semiconductor device.

FIG. 25 schematically illustrates an example electronic system including a semiconductor device.

FIG. 26 illustrates a schematic perspective view showing an example electronic system including a semiconductor device.

FIG. 27 and FIG. 28 illustrate schematic cross-sectional views showing example semiconductor packages.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

To clearly describe the present invention, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or above the object portion and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

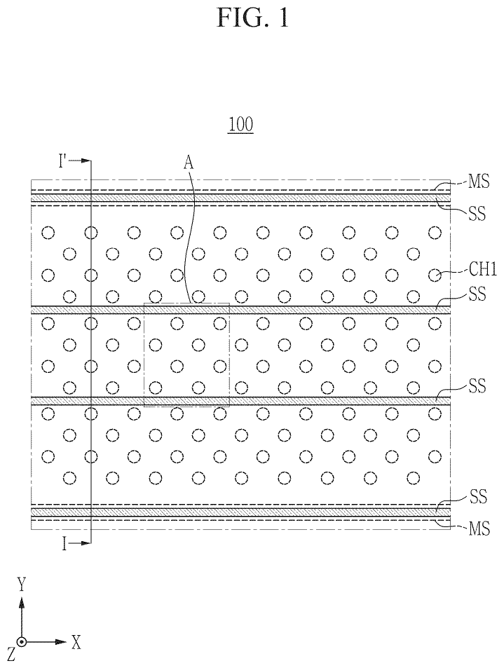

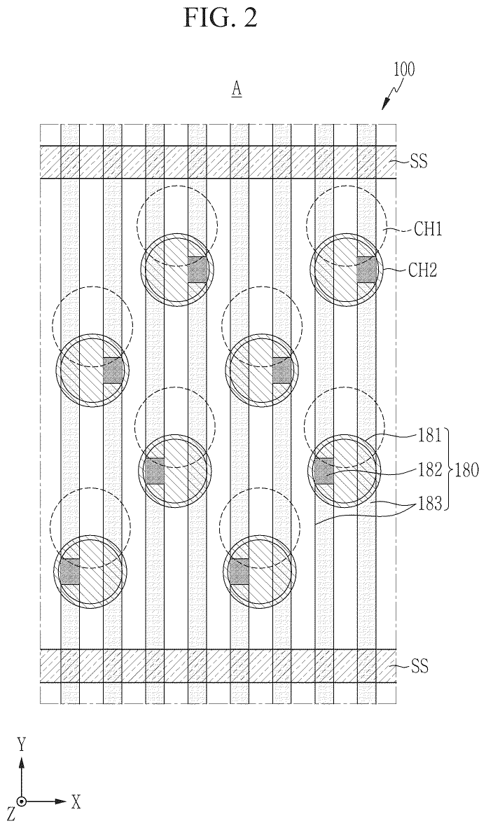

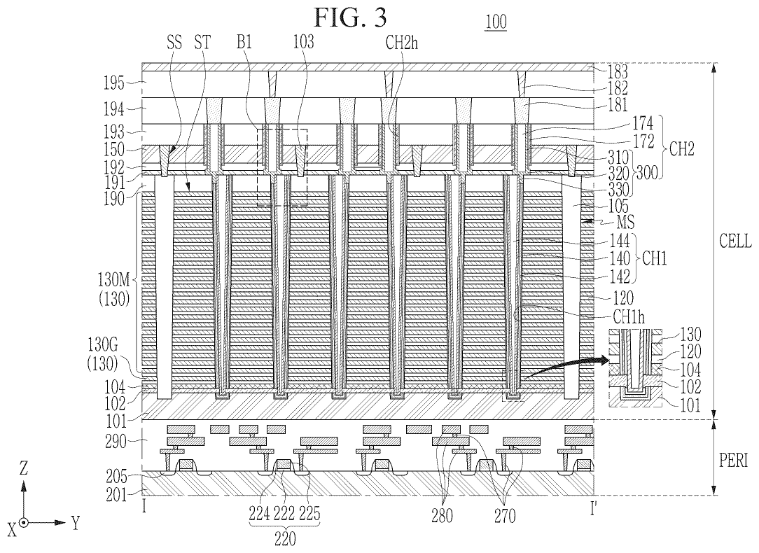

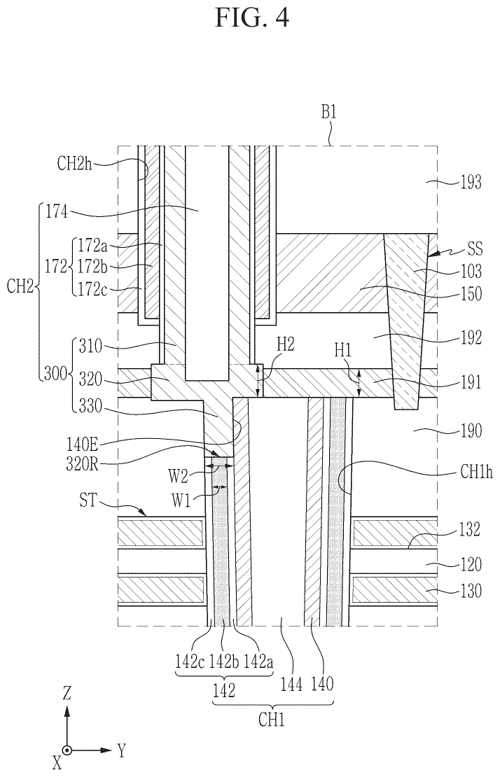

FIG. 1 illustrates a schematic top plan view of an example semiconductor device. FIG. 2 illustrates an enlarged view of a region A of FIG. 1. FIG. 3 illustrates a cross-sectional view taken along a line I-I′ of FIG. 1. FIG. 4 illustrates an enlarged cross-sectional view of a region B1 of FIG. 3.

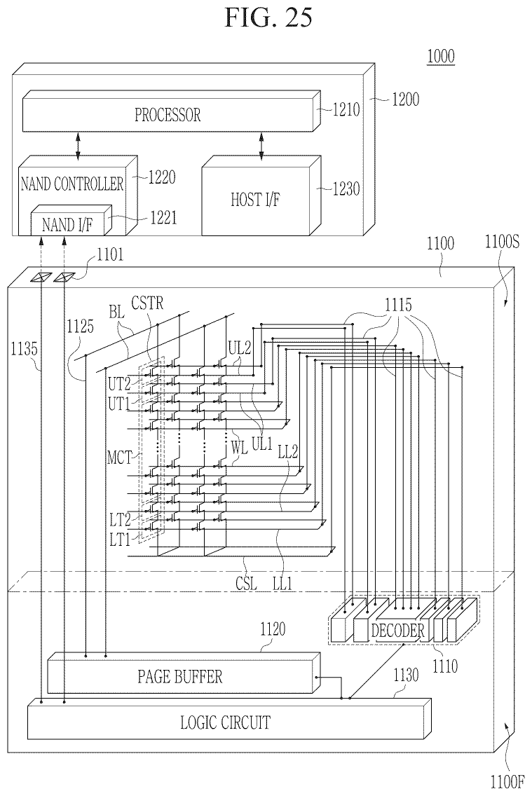

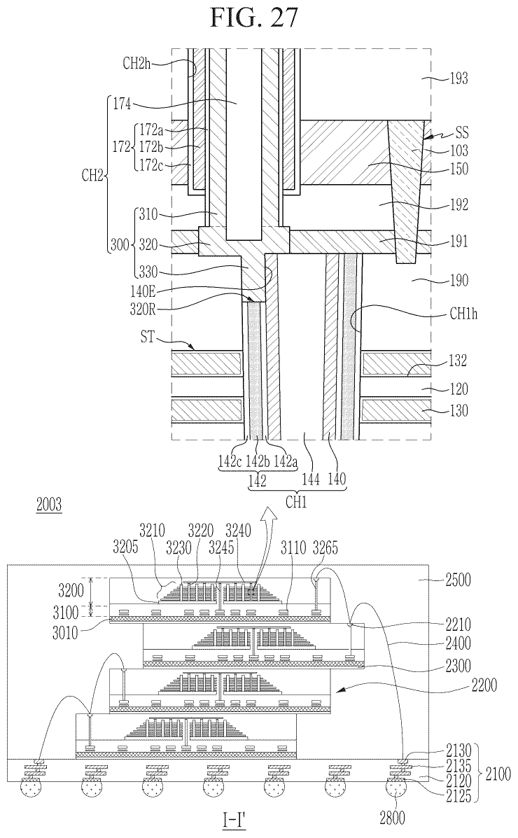

First, referring to FIGS. 1 to 3, the example semiconductor device 100 according to an implementation may include a memory cell region CELL and a peripheral circuit region PERI stacked vertically. For example, the peripheral circuit region PERI and the cell region CELL may respectively be portions corresponding to a first structure 1100F and a second structure 1100S of a semiconductor device 1100 included in an electronic system 1000 illustrated in FIG. 25. Alternatively, the peripheral circuit region PERI and the cell region CELL may be portions including a first structure 3100 and a second structure 3200, respectively, of a semiconductor chip 2200 illustrated in FIG. 27.

The memory cell region CELL may be positioned at an upper end of the peripheral circuit region PERI. However, the present disclosure is not limited thereto, and in some implementations, the semiconductor device 100 may include a memory cell region CELL and a peripheral circuit region PERI positioned separately on one substrate. That is, the memory cell region CELL and the peripheral circuit region PERI may not overlap vertically. In some cases, the memory cell region CELL may be positioned at a lower end of the peripheral circuit region PERI.

The peripheral circuit region PERI may include a base substrate 201, circuit elements 220 positioned on the base substrate 201, circuit contact plugs 270, and circuit wiring lines 280.

The base substrate 201 may have an upper surface extending in a first direction (a direction X) and a second direction (a direction Y). Separate element separation layers may be disposed on the base substrate 201 to define an active region. Source/drain regions 205 containing impurities may be positioned in a portion of the active region. The base substrate 201 may include a semiconductor material, e.g., a group IV semiconductor, a group III-V compound semiconductor, or a group II-VI compound semiconductor. The base substrate 201 may be provided as a bulk wafer or an epitaxial layer. However, the present disclosure is not limited thereto.

Circuit elements 220 may include horizontal transistors. Each of the circuit elements 220 may include a circuit gate dielectric layer 222, a spacer layer 224, and a circuit gate electrode 225. Source/drain regions 205 may be positioned at opposite sides of the circuit gate electrode 225.

A peripheral area insulating layer 290 may be disposed above the circuit element 220 on the base substrate 201. Circuit contact plugs 270 may extend through the peripheral region insulating layer 290 to be connected to the source/drain regions 205.

An electrical signal may be applied to the circuit elements 220 by the circuit contact plugs 270. In a region not illustrated, the circuit contact plugs 270 may also be connected to the circuit gate electrode 225. The circuit wiring lines 280 may be connected to the circuit contact plugs 270 and may be positioned in multiple layers.

In an implementation, the semiconductor device 100 may be manufactured by first manufacturing the peripheral circuit region PERI, and then forming the substrate 101 at an upper portion of the memory cell region CELL. The substrate 101 may have a same size as that of the base substrate 201 or may be formed to be smaller than the base substrate 201.

The memory cell region CELL may include a substrate 101, first and second horizontal conductive layers 102 and 104, a stacked structure ST, a first channel structure CH1, an insulating pattern 191, a selection gate electrode 150, and a second channel structure CH2, disposed on the substrate 101. Herein, the stacked structure ST may include a plurality of gate electrodes 130 and interlayer insulating layers 120 that are alternately stacked.

The substrate 101 may have an upper surface extending in a first direction (a direction X) and a second direction (a direction Y). The substrate 101 may include a semiconductor material, e.g., a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, an epitaxial layer, a silicon on insulator (SOI) layer, a semiconductor on insulator (SeOI) layer, or the like. However, the present disclosure is not limited thereto.

The first and second horizontal conductive layers 102 and 104 may be stacked on an upper surface of the substrate 101. The first horizontal conductive layer 102 may function as at least part of a common source line of the semiconductor device 100, for example, or may function as a common source line together with the substrate 101. As illustrated in the enlarged view of FIG. 3, the first horizontal conductive layer 102 may be directly connected to the first channel layer 140 at a side of the first channel layer 140.

The first and second horizontal conductive layers 102 and 104 may each include a semiconductor material, e.g., polycrystalline silicon. In this case, at least the first horizontal conductive layer 102 may be a layer doped with impurities of a same conductivity type as that of the substrate 101, and the second horizontal conductive layer 104 may be a doped layer or a layer containing impurities diffused from the first horizontal conductive layer 102. However, a material of the second horizontal conductive layer 104 is not limited to a semiconductor material and, in some implementations, it may be replaced by an insulating layer.

The gate electrodes 130 may be spaced apart in a third direction (a direction Z) on the substrate 101 to form a stacked structure ST. The gate electrodes 130 may include a ground gate electrode 130G forming a gate of a ground selection transistor and memory gate electrodes 130M forming a plurality of memory cells. A number of the memory gate electrodes 130M forming memory cells may be determined according to capacity of the semiconductor device 100. For example, the ground gate electrodes 130G may be one or two or more and may have a same or different structure as or from the memory gate electrodes 130M.

In some implementations, the gate electrodes 130 may be positioned below the ground gate electrodes 130G and may further include a gate electrode forming an erase transistor used in an erase operation using a gate induced leakage current (GIDL) phenomenon. Furthermore, some of the gate electrodes 130 (e.g., memory gate electrodes 130M adjacent to the ground gate electrode 130G) may be dummy gate electrodes.

The semiconductor device 100 according to an implementation may further include a gate dielectric layer 132 surrounding the gate electrodes 130. The gate dielectric layer 132 may be positioned between the gate electrodes 130 and the interlayer insulating layer 120 and between the gate electrodes 130 and the first channel structure CH1.

The interlayer insulating layers 120 may be positioned between the gate electrodes 130 and may be alternately disposed with the gate electrodes 130 in the third direction (the direction Z). Like the gate electrodes 130, the interlayer insulating layers 120 may be positioned to be spaced apart from each other in the third direction (the direction Z) on an upper surface of the substrate 101. The interlayer insulating layers 120 may include an insulating material such as a silicon oxide or a silicon nitride, but the present is not limited thereto.

Each first channel structure CH1 may form one memory cell string and may be positioned in rows and columns on the substrate 101 and spaced apart from each other. For example, the first channel structure CH1 may be positioned to form a grid pattern in a plan view where the first direction (the direction X) and the second direction (the direction Y) intersect or may be positioned in a zigzag shape in one direction. As an example, the first channel structures CH1 may be positioned in a zigzag fashion by a plurality of (e.g., 6) channel structures arranged in a first row and a plurality of (e.g., 6) channel structures arranged in a second row between adjacent separation regions MS, but the present disclosure is not limited to thereto, and an arrangement form of the first channel structures CH1 may be changed in various ways.

Each of the first channel structures CH1 may be provided in a first channel hole CH1h extending through the stacked structure ST. That is, the first channel structures CH1 may extend in the third direction (the direction Z). Each of the first channel structures CH1 may have a pillar shape and may have an inclined side surface that becomes narrower as it approaches the substrate 101 depending on an aspect ratio thereof.

Referring further to FIG. 4, the first channel structure CH1 of the semiconductor device 100 according to an implementation may include a first channel layer 140, a first dielectric layer 142, and a first core insulating layer 144.

The first core insulating layer 144 may be provided in a central region of the first channel structure CH1, and the first channel layer 140 may be disposed surrounding a sidewall of the first core insulating layer 144. For example, the first core insulating layer 144 may have a columnar shape (e.g., a circular cylindrical shape or a polygonal columnar shape), and the first channel layer 140 may have an annular shape such as an annulus. However, the implementation is not limited thereto, and, for example, the first core insulating layer 144 may not be provided and the first channel layer 140 may have a columnar shape (e.g., a circular cylindrical shape or a polygonal columnar shape).

In an implementation, a portion of the first channel layer 140 and a portion of the first core insulating layer 144 may contact a second channel layer 300. For example, a portion of an upper surface of the first channel layer 140 and a portion of an upper surface of the first core insulating layer 144 may contact a second portion 320 of the second channel layer 300, and a remaining portion of the upper surface of the first channel layer 140 and a remaining portion of the upper surface of the first core insulating layer 144 may be in contact with the insulating pattern 191. Furthermore, a portion of an outer surface 140E of the first channel layer 140 may contact a third portion 330 of the second channel layer 300. Accordingly, the first channel layer 140 may be electrically connected to the second channel layer 300. A detailed description thereof will be provided later in a description of the second channel layer 300.

The first channel layer 140 may extend through the first and second horizontal conductive layers 102 and 104. The first channel layer 140 may be electrically connected to the first and second horizontal conductive layers 102 and 104. For example, a portion of a side surface of the first channel layer 140 may be electrically connected by directly contacting a side surface of the first horizontal conductive layer 102.

The first channel layer 140 may include a semiconductor material, e.g., polycrystalline silicon. Herein, the semiconductor material may be an undoped material or a material containing p-type or n-type impurities. The core insulating layer 144 may include various insulating materials. For example, the first core insulating layer 144 may include a silicon oxide, a silicon oxynitride, or a combination thereof. However, materials of the first channel layer 140 and the first core insulating layer 144 are not limited thereto.

The first dielectric layer 142 may be disposed between the gate electrodes 130 and the first channel layer 140. The first dielectric layer 142 may be disposed between the interlayer insulating layers 120 and the first channel layer 140.

In an implementation, a portion of the first dielectric layer 142 may be in contact with the second channel layer 300. For example, a portion of an upper surface of the first dielectric layer 142 may be in contact with the third portion 330 of the second channel layer 300, and a remaining portion of the upper surface of the first dielectric layer 142 may be in contact with the insulating pattern 191. This may be due to process characteristics of etching a portion of the first dielectric layer 142 positioned below the insulating pattern 191 and forming the second channel layer 300 in an etched space thereof.

Furthermore, an upper surface of a first side portion and an upper surface of a second side portion of the first dielectric layer 142 may be positioned at different levels. For example, the upper surface of the first side portion of the first dielectric layer 142 may be positioned at a lower level than that of the upper surface of the second side portion. Herein, the first side portion of the first dielectric layer 142 may refer to a portion where the second channel layer 300 is disposed at the upper portion.

As illustrated in FIG. 4, the first dielectric layer 142 of the semiconductor device 100 according to an implementation may include a first channel insulating layer 142a, a first ferroelectric layer 142b, and a first blocking layer 142c sequentially stacked from the outer surface 140E of the first channel layer 140.

The first channel insulating layer 142a may surround the first channel layer 140. At least a portion of an upper surface of the first channel insulating layer 142a may be in contact with the second channel layer 300. A remaining portion of the upper surface of the first channel insulating layer 142a may be in contact with the insulating pattern 191. The first channel insulating layer 142a may include various insulating materials. For example, a remaining portion of the upper surface of the first channel insulating layer 142a may be in contact with the insulating pattern 191.

The first ferroelectric layer 142b may surround the first channel insulating layer 142a. The first ferroelectric layer 142b may be disposed between the gate electrodes 130 and the first channel insulating layer 142a and between the interlayer insulating layers 120 and the first channel insulating layer 142a. The first ferroelectric layer 142b may be provided between the first channel insulating layer 142a and the gate electrodes 130.

In an implementation, a portion of the first ferroelectric layer 142b may contact the second channel layer 300. For example, a portion of an upper surface of the first ferroelectric layer 142b may be in contact with the third portion 330 of the second channel layer 300, and a remaining portion of the upper surface of the first ferroelectric layer 142b may be in contact with the insulating pattern 191. This may be due to process characteristics of etching a portion of the first ferroelectric layer 142b positioned below the insulating pattern 191 and forming the second channel layer 300 in an etched space thereof.

Furthermore, an upper surface of a first side portion and an upper surface of a second side portion of the first ferroelectric layer 142b may be positioned at different levels. For example, the upper surface of the first side portion of the first ferroelectric layer 142b may be positioned at a lower level than that of the upper surface of the second side portion. Herein, the first side portion of the first ferroelectric layer 142b may refer to a portion where the second channel layer 300 is disposed at the upper portion.

The first ferroelectric layer 142b may include a ferroelectric material. For example, the first ferroelectric layer 142b may include an Hf compound having ferroelectric characteristics. As an example, the first ferroelectric layer 142b may include HfO₂, HfZnO, HfSiO, HfSiON, HfTaO, HfTiO, HfZrO, or a combination thereof. Furthermore, the first ferroelectric layer 142b may include a ferroelectric material with a perovskite structure, such as PZT (PbZrxTi1-xO₃), BaTiO₃, PbTiO₃, etc. The first ferroelectric layer 142b may include at least one dopant selected from carbon (C), silicon (Si), magnesium (Mg), aluminum (AI), yttrium (Y), nitrogen (N), germanium (Ge), tin (Sn), strontium (Sr), lead (Pb), Calcium (Ca), barium (Ba), titanium (Ti), zirconium (Zr), gadolinium (Gd), and lanthanum (La). Furthermore, the first ferroelectric layer 142b may be made of a crystalline material. For example, the first ferroelectric layer 142b may have a crystal structure of an orthorhombic system. In an implementation, the first ferroelectric layer 142b may include a material having an etch selectivity with respect to the cell region insulating layer 190, the insulating pattern 191, and the first channel layer 140.

In an implementation, in a case where the first ferroelectric layer 142b includes a ferroelectric, the first ferroelectric layer 142b may be configured to have various states of polarization depending on a voltage applied between the gate electrodes 130 and the first channel layer 140. Specifically, residual polarization may be generated within the first ferroelectric layer 142b by the voltage applied between the gate electrodes 130 and the first channel structure CH1. Herein, a magnitude of the residual polarization generated in the first ferroelectric layer 142b may be determined by polarization-voltage (PV) hysteresis characteristics that also consider a process through which the residual polarization generated in the first ferroelectric layer 142b has passed in addition to a magnitude of the voltage applied between the gate electrodes 130 and the first channel layer 140. The generated residual polarization may be stored in the first ferroelectric layer 142b, and signal information may be stored non-volatilely by the stored residual polarization. That is, the first ferroelectric layer 142b may function as a non-volatile memory layer.

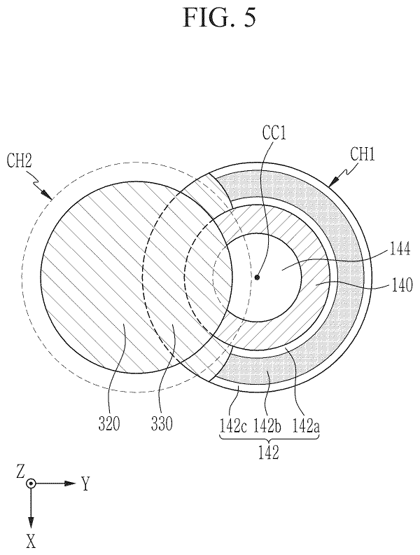

Meanwhile, a degree of residual polarization generated and/or stored by the first ferroelectric layer 142b may be determined by a width of the first ferroelectric layer 142b and a distance between the first ferroelectric layer 142b and the first channel layer 140. Accordingly, according to an implementation, in order for the first ferroelectric layer 142b to function as a non-volatile memory layer, the width of the first ferroelectric layer 142b needs to be within a predetermined range. Herein, the width of the first ferroelectric layer 142b may refer to a width along a radial direction from a center CC1 of the first channel structure CH1 (as shown in FIG. 5). That is, in an implementation, the first ferroelectric layer 142b may have a first width W1 along the radial direction from the center CC1 of the first channel structure CH1. In this case, the first width W1 in the radial direction from the center CC1 of the first channel structure CH1 of the first ferroelectric layer 142b may be substantially equal to the width of the first ferroelectric layer 142b in the second direction (the direction Y) in the cross section in the second direction (the direction Y) and the third direction (the direction Z).

The first blocking layer 142c may surround the first ferroelectric layer 142b. The first blocking layer 142c may extend to have a conformal shape along an inner wall of the first channel hole CH1h. The first blocking layer 142c may be positioned to cover the inner wall and a lower surface of the first channel hole CH1h. The first ferroelectric layer 142c may be disposed between the gate electrodes 130 and the first ferroelectric layer 142b and between the interlayer insulating layers 120 and the first ferroelectric layer 142b. The first blocking layer 142c may be provided between the first ferroelectric layer 142b and the gate electrode 130.

In an implementation, a portion of the first blocking layer 142c may contact the second channel layer 300. For example, a portion of an upper surface of the first blocking layer 142c may be in contact with the third portion 330 of the second channel layer 300, and a remaining portion of the upper surface of the first blocking layer 142c may be in contact with the insulating pattern 191. This may be due to process characteristics of etching a portion of the first blocking layer 142c positioned below the insulating pattern 191 and forming the second channel layer 300 in an etched space thereof.

Furthermore, an upper surface of a first side portion and an upper surface of a second side portion of the first blocking layer 142c may be positioned at different levels. For example, the upper surface of the first side portion of the first blocking layer 142c may be positioned at a lower level than that of the upper surface of the second side portion. Herein, the first side portion of the first blocking layer 142c may refer to a portion where the second channel layer 300 is disposed at the upper portion. The first blocking layer 142c may include various insulating materials. The first blocking layer 142c may include a material such as a silicon oxide or a silicon nitride, but the present disclosure is not limited thereto.

The semiconductor device 100 according to an implementation may further include separation regions MS.

The separation regions MS may extend through the cell region insulating layer 190, the stacked structure ST including the gate electrodes 130 and the interlayer insulating layer 120, and the first and second horizontal conductive layers 102 and 104. The separation regions MS extend in the third direction (the direction Z) and may be connected to the substrate 101.

As illustrated in FIG. 3, the separation regions MS may be spaced apart from each other along the second direction (the direction Y) and may be positioned in parallel with each other. The separation regions MS may separate the gate electrodes 130 from each other in the second direction (the direction Y).

The separation regions MS may have a shape having a width that decreases toward the substrate 101 due to a high aspect ratio thereof. A separation insulating layer 105 may be disposed within the separation regions MS. The separation insulating layer 105 may include at least one of a silicon oxide, a silicon nitride, or a silicon oxynitride. However, the present disclosure is not limited thereto, and in some implementations, a conductive material layer may be disposed within the separation regions MS.

The semiconductor device 100 according to an implementation may further include the cell region insulating layer 190.

The cell region insulating layer 190 may cover the stacked structure ST including the gate electrodes 130 and the interlayer insulating layers 120. The cell region insulating layer 190 may cover the separation regions MS and/or at least a portion of side surfaces of the first channel structure CH1, e.g., a portion extending upward from the stacked structure ST.

In some implementations, an upper surface of the cell region insulating layer 190 may be positioned at substantially a same level as that of an upper surface of each of the first channel structures CH1, and the upper surface of the cell region insulating layer 190 may be positioned at substantially the same level as that of a surface of each of the separation regions MS.

The cell region insulating layer 190 may include at least one of a silicon oxide, a silicon nitride, or a silicon oxynitride. However, the present disclosure is not limited thereto.

An insulating pattern 191 may be positioned on the stacked structure ST. That is, the insulating pattern 191 may be positioned on the first channel structure CH1 and the separation regions MS. The insulating pattern 191 may extend in the first direction (the direction X) and the second direction (the direction Y). The insulating pattern 191 may be in contact with the first channel structure CH1. For example, as described above, the insulating pattern 191 may contact the first core insulating layer 144, the first channel layer, and the first dielectric layer 142.

In an implementation, a first thickness H1 along the third direction (direction Z) of the insulating pattern 191 may be greater than or equal to the first width W1 along the radial direction of the first channel structure CH1 of the first ferroelectric layer 142b. Alternatively, on a cross section in the second direction (the direction Y) and the third direction (the direction Z), the first thickness H1 of the insulating pattern 191 along the third direction (the direction Z) may be greater than or equal to the width of the first ferroelectric layer 142b along the second direction (direction Y). Furthermore, the first thickness H1 of the insulating pattern 191 along the third direction (the direction Z) may be substantially equal to or smaller than a thickness of the gate electrodes 130 in the third direction (the direction Z).

The insulating pattern 191 may include a material different material from that of the cell region insulating layer 190. The insulation pattern 191 may include a material having an etching ratio for the cell region insulating layer 190 and a first upper insulating layer 192 which will be described later. For example, the insulating pattern 191 may include a silicon nitride, but the present disclosure is not limited thereto.

In an implementation, the insulating pattern 191 may have an integrated structure in which portions excluding the second channel hole CH2h, which will be described later, are connected to each other in a plan view including a first direction (the direction X) and a second direction (the direction Y). This may be due to process characteristics of forming a plurality of penetrating portions in the single-layer insulating pattern 191 and forming the second channel layer 300 in the penetrating portions.

Furthermore, the insulating pattern 191 may be penetrated by an upper separation region SS, which will be described later. Accordingly, although insulating patterns 191 of the semiconductor device 100 according to an implementation have an integrated structure in which they are connected to each other in a plan view, residual substances generated during the manufacturing process may be discharged through the upper separation region SS.

The selection gate electrode 150 may be positioned on the insulating pattern 191. The selection gate electrode 150 may be positioned spaced apart from the first channel structure CH1 in the third direction (the direction Z).

In an implementation, the selection gate electrode 150 may include a different material from that of the gate electrodes 130. For example, the selection gate electrode 150 may be a layer of a semiconductor material such as polycrystalline silicon. In this case, a thickness of the selection gate electrode 150 along the third direction (the direction Z) may be thicker than a thickness of each of the gate electrodes 130 along the third direction (the direction Z). However, the gate electrodes 130 may include at least one of a nitride (e.g., TiN or TaN) or a transition metal (e.g., Ti or Ta).

The selection gate electrode 150 may be a string selection line forming a string selection transistor (see ‘UT1 and UT2’ in FIG. 25).

FIG. 3 illustrates one selection gate electrode 150, but the present disclosure is not limited thereto. For example, a plurality of selection gate electrodes 150 may be provided. In this case, the selection gate electrodes 150 may be positioned to be spaced apart from each other along the third direction (the direction Z).

The semiconductor device 100 according to an implementation may further include first to fourth upper insulating layers 192 to 195.

A first upper insulating layer 192 may be disposed between the selection gate electrode 150 and the insulating pattern 191. The selection gate electrode 150 may be spaced apart from the insulating pattern 191 by the first upper insulating layer 192. The first upper insulating layer 192 may include a different material from that of the insulating pattern 191. The first upper insulating layer 192 may include, e.g., a silicon oxide.

Second to fourth upper insulating layers 193, 194, and 195 may be sequentially stacked on the selection gate electrode 150. The second to fourth upper insulating layers 193, 194, and 195 may each include at least one of a silicon oxide, a silicon nitride, or a silicon oxynitride.

The semiconductor device 100 according to an implementation may further include an upper separation region SS.

The upper separation region SS may extend through the selection gate electrode 150 and the insulating pattern 191. The upper separation region SS may extend in the first direction (the direction X). The upper separation region SS may extend through the selection gate electrode 150 and the insulating pattern 191 and may extend into the cell region insulating layer 190. In addition, an upper surface of the separation region SS may be positioned at substantially a same level as an upper surface of the gate electrode 150. A lower surface of the upper separation region SS may be positioned at a higher level than that of the upper surface of the stacked structure ST.

In an implementation, a gap between adjacent separation regions MS in the second direction (the direction Y) may be greater than a gap between upper separation regions SS adjacent in the second direction (the direction Y). That is, in a plan view, at least a portion of the upper separation region SS may be positioned between adjacent separation regions MS in the second direction (the direction Y).

The upper separation region SS and the selection gate electrode 150 are positioned at a higher level than that of the separation regions MS and the first channel structure CH1, and thus dummy structures between the first channel structures CH1 may be omitted, and accordingly, a semiconductor device 100 with improved integration may be provided.

An upper separation insulating layer 103 may be positioned in the upper separation region SS. The upper separation insulating layer 103 may include an insulating material such as a silicon oxide. However, the present disclosure is not limited thereto, and in some implementations, the upper separation region SS may include at least some of materials of the second channel structure CH2, which will be described later.

Each of the second channel structures CH2 may be provided in the second channel hole CH2h extending through the selection gate electrode 150. The second channel structure CH2 may be positioned on the first channel structure CH1. Each of the second channel structures CH2 may extend in the third direction (the direction Z) to be electrically connected to each of the first channel structures CH1. The second channel structure CH2 may be a string selection channel structure of a string selection transistor (see ‘UT1 and UT2’ in FIG. 25).

The second channel structures CH2 may be positioned in rows and columns on the insulating pattern 191 and spaced apart from each other. For example, the second channel structure CH2 may be positioned to form a grid pattern in a plan view where the first direction (the direction X) and the second direction (the direction Y) intersect or may be positioned in a zigzag shape in one direction.

In an implementation, the second channel structure CH2 may be positioned spaced apart from the first channel structure CH1 in the second direction (the direction Y). That is, at least a portion of the second channel structure CH2 may overlap the first channel structure CH1 in the third direction (the direction Z). For example, some regions of the second channel structure CH2 may overlap the first channel structure CH1, and other regions may overlap the cell region insulating layer 190. In other words, a center of the second channel structure CH2 may be spaced apart from a center of the first channel structure CH1 in the second direction (the direction Y).

A diameter of the second channel structure CH2 may be smaller than a diameter of the first channel structure CH1. In an implementation, on a cross section in the second direction (the direction Y) and the third direction (the direction Z), a diameter of the second channel structure CH2 may be substantially equal to a width of the second channel structure CH2 in the second direction (Y direction). That is, the width of the second channel structure CH2 in the second direction (the direction Y) may be smaller than a width of the first channel structure CH1 in the second direction (Y direction). Accordingly, the second channel structure CH2 may be stably positioned on the first channel structure CH1. However, the implementation is not limited thereto, and a diameter of the second channel structure CH2 may be equal to or greater than a diameter of the first channel structure CH1.

The second channel structures CH2 may each have a columnar shape. Unlike the first channel structure CH1 described above, the width of the second channel structure CH2 may be constant. That is, a diameter of an upper surface of the second channel structure CH2 and a diameter of a lower surface of the second channel structure CH2 may be substantially the same. However, the present disclosure is not limited thereto, and in some implementations, the second channel structure CH2 may include an inclined side surface that becomes narrower as it approaches the substrate 101.

In an implementation, second channel structure CH2 may include a second buried insulating layer 174, a second channel layer 300, and a second dielectric layer 172.

The second channel layer 300 may extend through the selection gate electrode 150 and the insulating pattern 191. The second channel layer 300 may extend through the selective gate electrode 150 and the insulating pattern 191 to be positioned on the first channel structure CH1. The second channel layer 300 may be electrically connected to the first channel structure CH1 by extending through the selection gate electrode 150 and the insulating pattern 191.

In an implementation, the second channel layer 300 may overlap at least a portion of the first channel structure CH1 in the third direction (the direction Z). For example, a portion of the second channel layer 300 may overlap each of the first channel structures CH1, and a remaining portion of the second channel layer 300 may overlap the cell region insulating layer 190.

The second channel layer 300 may include a semiconductor material. For example, the second channel layer 300 may include a semiconductor material such as polycrystalline silicon, and the semiconductor material may be an undoped material or a material containing p-type or n-type impurities.

In an implementation, the second channel layer 300 may include a first portion 310 extending through the selection gate electrode 150, a second portion 320 extending through the insulating pattern 191 and is in contact with an upper surface of the first channel layer 140, and a third portion 330 protruding from a lower surface of the second portion 320 and contacting the outer surface 140E of the first channel layer 140. A detailed description thereof will be provided later with further reference to FIG. 5.

The semiconductor device 100 according to an implementation may further include an upper wiring structure 180.

The upper wiring structure 180 may be electrically connected to the first and second channel structures CH1 and CH2. The upper wiring structure 180 may include studs 181, contact plugs 182, and an upper wire 183. The studs 181 may extend through a third upper insulating layer 194 to contact an upper surface of each of the second channel structures CH2. The upper wiring structure 180 may include a conductive material.

In FIG. 2, an area of each of the studs 181 in a plan view is illustrated to be smaller than an area of each of the second channel structures CH2 in a plan view, but this is to illustrate the studs 181, and the area of each of the studs 181 in the plan view may be substantially the same as or larger than the area of each of the second channel structures CH2 in the plan view.

The contact plugs 182 may extend through the fourth upper insulating layer 195 to be connected to the studs 181. The upper wire 183 may be positioned on the contact plugs 182 and the fourth upper insulating layer 195. A portion of the upper wire 183 may be bit lines (see ‘BL’ in FIG. 25) that contact the contact plugs 182. The bit lines may extend in the second direction (the direction Y), as illustrated in FIGS. 1 and 2. That is, the upper wire 183 may intersect the upper separation region SS. The bit lines may be electrically connected to the second channel structure CH2 through the contact plugs 182.

Hereinafter, the second channel structure CH2 including the second channel layer 300 will be described in detail with further reference to FIG. 5.

FIG. 5 illustrates a top plan view schematically showing a channel structure of an example semiconductor device.

Referring to FIGS. 4 and 5, as described above, the second channel structure CH2 may include a second buried insulating layer 174, a second channel layer 300, and a second dielectric layer 172.

The second channel layer 300 of the semiconductor device 100 according to an implementation may extend through the selection gate electrode 150 and the insulating pattern 191. The second channel layer 300 may be electrically connected to the first channel structure CH1 by extending through the selection gate electrode 150 and the insulating pattern 191.

In an implementation, the second channel layer 300 may overlap at least a portion of the first channel structure CH1 in the third direction (the direction Z). For example, a portion of the second channel layer 300 may overlap each of the first channel structures CH1, and a remaining portion of the second channel layer 300 may overlap the cell region insulating layer 190. As an example, as illustrated in FIG. 5, in a plan view, a center of the second portion 320 of the second channel layer 300 may be spaced apart from the center CC1 of the first channel structure CH1 in the second direction (the direction Y) and overlap a portion of the first channel structure CH1 in the third direction (the direction Z). However, the present disclosure is not limited thereto, and a center of the second portion 320 of the second channel layer 300 may be positioned spaced apart from the center CC1 of the first channel structure CH1 in a different direction.

In an implementation, the second channel layer 300 may include a first portion 310 extending through the selection gate electrode 150, a second portion 320 extending through the insulating pattern 191 and contacting an upper surface of the first channel layer 140, and a third portion 330 protruding from a lower surface of the second portion 320 and contacting the outer surface 140E of the first channel layer 140.

The first portion 310 of the second channel layer 300 may extend through the selection gate electrode 150. The second core insulating layer 174 may be provided in a central region of the second channel structure CH2, and the first portion 310 may be positioned surrounding a sidewall of the second core insulating layer 174. For example, the second core insulating layer 174 may have a columnar shape (e.g., a circular cylindrical shape or a polygonal columnar shape), and the first portion 310 may have an annular shape such as an annulus. However, the implementation is not limited thereto, and, for example, the second core insulating layer 174 may not be provided and the first portion 310 may have a columnar shape (e.g., a circular cylindrical shape or a polygonal columnar shape). Furthermore, the first portion 310 may extend in the third direction (the direction Z) within the second channel hole CH2h.

The first portion 310 may include a semiconductor material, e.g., polycrystalline silicon. Herein, the semiconductor material may be an undoped material or a material containing p-type or n-type impurities. The core insulating layer 144 may include various insulating materials. For example, the second core insulating layer 174 may include a silicon oxide, a silicon oxynitride, or a combination thereof. However, materials of the first portion 310 and the first core insulating layer 144 are not limited thereto.

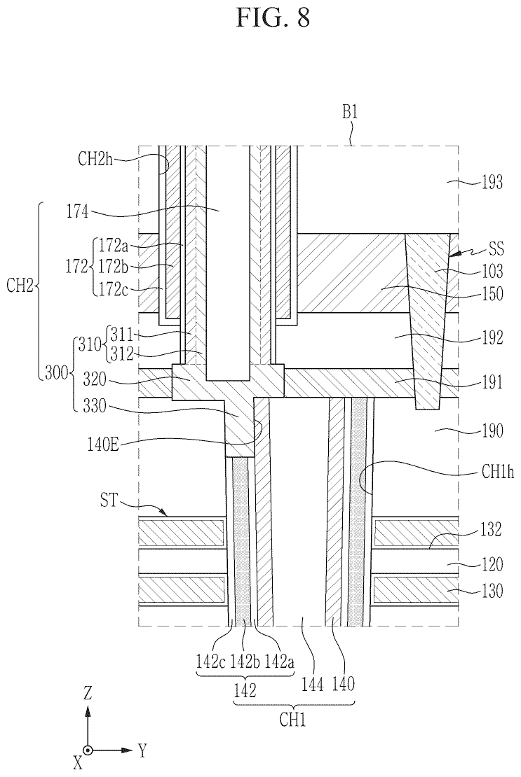

In an implementation, as illustrated in FIG. 4, the first portion 310 is illustrated as being formed as a single layer. In this case, a portion of the first portion 310 and a remaining portion of the first portion 310 may be formed through a separate process. For example, a portion of the first portion 310 adjacent to the second core insulating layer 174 and the remaining portion of the first portion 310 adjacent to the second channel insulating layer 172a may be formed by a separate process. In this case, the portion of the first portion 310 formed through the separate process and the remaining portion of the first portion 310 may each include a same material. Accordingly, there may not be an interface between the portion of the first portion 310 and the remaining portion of the first portion 310. However, the present disclosure is not limited thereto, the first portion 310 may be formed to include multiple layers. In this case, an interface may exist between a portion of the first portion 310 and a remaining portion of the first portion 310, that is, a boundary may be visible between a portion of the first portion 310 and the remaining portion of the first portion 310. This will be described later with reference to FIG. 8.

The second portion 320 of the second channel layer 300 may extend through the insulating pattern 191. The second portion 320 may be positioned on the upper surface of the first channel structure CH1. The second portion 320 may extend through the insulating pattern 191 to be connected to the first channel structure CH1. For example, the second portion 320 may extend through the insulating pattern 191 to contact an upper surface of the first channel layer 140. That is, the second portion 320 may be electrically connected to the first channel layer 140.

In one implementation, at least a portion of the second portion 320 may overlap the first channel structure CH1 in the third direction (the direction Z). For example, as illustrated in FIG. 5, in a plan view, a center of the second portion 320 may be positioned spaced apart from the center CC1 of the first channel structure CH1 in the second direction (the direction Y). In this case, at least a portion of the second portion 320 may overlap the first channel structure CH1 in the third direction (the direction Z). However, the present disclosure is not limited thereto, and a center of the second portion 320 may be positioned spaced apart from the center CC1 of the first channel structure CH1 in a different direction.

Furthermore, as illustrated in FIG. 4, in a cross section including the second direction (the direction Y) and the third direction (the direction Z), the second portion 320 may extend from an edge of the third portion 330 to opposite sides at an upper portion of the third portion 330. For example, the second portion 320 extends from the edge of the third portion 330 to the opposite sides to be positioned on the cell region insulating layer 190 and the first channel structure CH1. In other words, a first side portion of the second portion 320 is positioned on an upper surface of the first channel structure CH1, and a second side portion of the second portion 320 may be positioned on an upper surface of the cell region insulating layer 190. As an example, the first side portion of the second portion 320 may be positioned on an upper surface of the first channel layer 140 and an upper surface of the first core insulating layer 144.

In an implementation, the second portion 320 may have a circular shape in a plan view. In this case, a diameter of the second portion 320 may be smaller than a diameter of the second dielectric layer 172. Herein, on a cross section in the second direction (the direction Y) and the third direction (the direction Z), a diameter of the second portion 320 may be substantially equal to a width of the second portion 320 in the second direction (the direction Y). That is, in an implementation, a width of the second portion 320 in the second direction (the Y direction) may be smaller than the width of the second dielectric layer 172 in the second direction (the Y direction). However, the present disclosure is not limited thereto, a diameter of the second portion 320 may be equal to or greater than a diameter of the second dielectric layer 172.

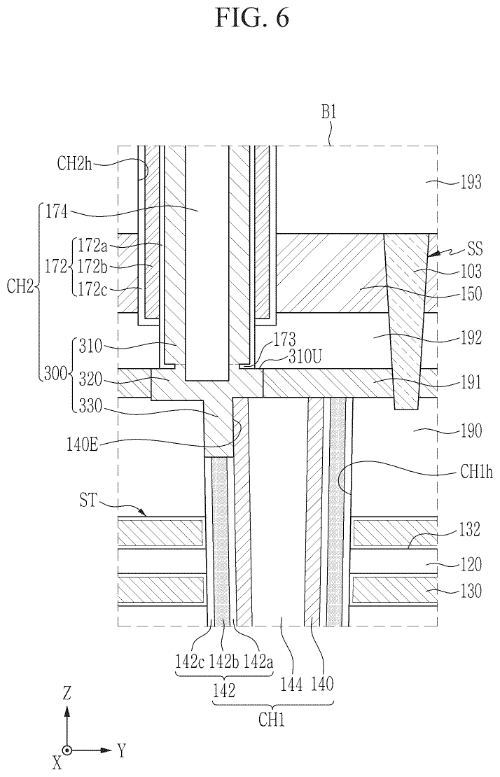

In an implementation, an upper surface of the second portion 320 may be in contact with a lower surface of the first portion 310. That is, the first portion 310 may completely overlap the second portion 320 in the third direction (the direction Z). Furthermore, the upper surface of the second portion 320 may contact the first upper insulating layer 192 and the second channel insulating layer 172a. However, the present disclosure is not limited thereto, the upper surface of the second portion 320 may be in contact with a portion of the lower surface of the first portion 310. This will be described later with reference to FIG. 6.

The upper surface of the second portion 320 may be positioned closer to the selection gate electrode 150 than the upper surface of the insulating pattern 191. That is, the upper surface of the second portion 320 may be positioned at a higher level than that of the upper surface of the insulating pattern 191. The upper surface of the second portion 320 may be positioned farther from the upper surface of the substrate 101 than the upper surface of the insulating pattern 191. Furthermore, the lower surface of the second portion 320 may be positioned farther from the selection gate electrode 150 than the lower surface of the insulating pattern 191. However, the present disclosure is not limited thereto, and the upper surface of the second portion 320 may be positioned at substantially a same level as that of the upper surface of the insulating pattern 191. This will be described later with reference to FIG. 6.

Accordingly, a second thickness H2 of the second portion 320 along the third direction (the direction Z) may be greater than the first thickness H1 along the third direction (the direction Z) of the insulating pattern 191. This is because at least a portion of the cell region insulating layer 190 and/or the first upper insulating layer 192 is etched together in an operation of etching the first ferroelectric layer 142b in a process of forming a channel recess 320R. However, the present disclosure is not limited thereto, and the second thickness H2 along the third direction (the direction Z) of the second portion 320 may be substantially equivalent to the first thickness H1 along the third direction (the direction Z) of the insulating pattern 191.

The third portion 330 of the second channel layer 300 may protrude from the lower surface of the second portion 320 toward the substrate 101.

The third portion 330 may be positioned on the first channel structure CH1. For example, the third portion 330 may be positioned on first dielectric layer 142. That is, the third portion 330 may be positioned on the first channel insulating layer 142a, the first ferroelectric layer 142b, and the first blocking layer 142c. Accordingly, the third portion 330 may overlap the first channel structure CH1 in the third direction (the direction Z). For example, the third portion 330 may completely overlap the first channel insulating layer 142a, the first ferroelectric layer 142b, and the first blocking layer 142c in the third direction (the direction Z).

In an implementation, the third portion 330 may fill the channel recess 320R. In this case, a lower surface of the channel recess 320R may be defined by the first dielectric layer 142. An inner wall of the channel recess 320R may be defined by the cell region insulating layer 190 and the first channel layer 140.

In an implementation, the third portion 330 may be positioned on the outer surface 140E of the first channel layer 140. For example, the third portion 330 may be positioned between the cell region insulating layer 190 and the first channel layer 140. The third portion 330 may overlap the cell region insulating layer 190 and the first channel layer 140 in the horizontal direction (first direction (the direction X) and/or second direction (the direction Y)). A side surface of the third portion 330 may contact the outer surface 140E of the first channel layer 140. Accordingly, the third portion 330 may be electrically connected to the first channel layer 140.

The third portion 330 may extend along a circumferential direction of the first channel structure CH1. For example, as illustrated in FIG. 5, the third portion 330 may extend along the circumferential direction of the first channel structure CH1 on the outer surface 140E of the first channel layer 140 in a plan view. In this case, in a plan view, an area where the third portion 330 extends along the circumferential direction of the first channel structure CH1 may be greater than an area of a portion where the third portion 330 overlaps the second portion 320. In other words, at least a portion of the third portion 330 may overlap the second portion 320 in the third direction (the direction Z). For example, at least a portion of the third portion 330 may overlap the second portion 320 in the third direction (the direction Z), and a remaining portion of the third portion 330 may not overlap the second portion 320 in the third direction (the direction Z). However, the present disclosure is not limited thereto, and for example, the area where the third portion 330 extends along the circumferential direction of the first channel structure CH1 may be substantially equal to the area of the portion where the second portion 320 overlaps the third portion 330.

The third portion 330 may have a constant width of the first channel structure CH1 along the circumferential direction. For example, the second width W2 in the radial direction from the center CC1 of the first channel structure CH1 of the third portion 330 may substantially be the same along the circumferential direction of the first channel structure CH1. In this case, the second width W2 in the radial direction from the center CC1 of the first channel structure CH1 of the third portion 330 may be greater than the first width W1 in the radial direction from the center CC1 of the first channel structure CH1 of the first ferroelectric layer 142b. This may be due to process characteristics of etching the first channel insulating layer 142a and the first blocking layer 142c together and forming the third portion 330 within an etched space in an operation of etching a portion of the first ferroelectric layer 142b.

For example, the second width W2 in the radial direction from the center CC1 of the first channel structure CH1 of the third portion 330 may be substantially equal to the second thickness H2 of the second portion 320 in the third direction (the direction Z). Accordingly, the second width W2 in the radial direction from the center CC1 of the first channel structure CH1 of the third portion 330 may be greater than the first thickness H1 of the insulating pattern 191 according to the third direction (the direction Z). However, the present disclosure is not limited thereto, the second width W2 in the radial direction from the center CC1 of the first channel structure CH1 of the third portion 330 may be greater than the second thickness H2 of the second portion 320 in the third direction (the direction Z).

This is because the second width W2 in the radial direction from the center CC1 of the first channel structure CH1 of the third portion 330 is substantially equal to the second thickness H2 along the third direction (the direction Z) of the second portion 320, and thus the second portion 320 and the third portion 330 may be formed together in an operation of forming the second portion 320 and the third portion 330. As a result, it may be possible to prevent an inner portion of a space for forming the second channel layer 300 from not being filled.

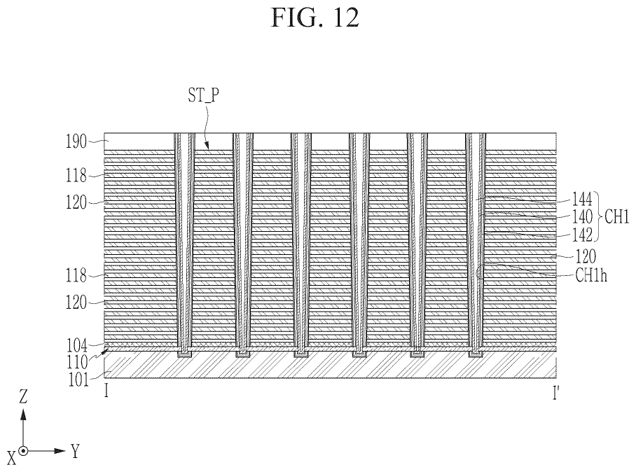

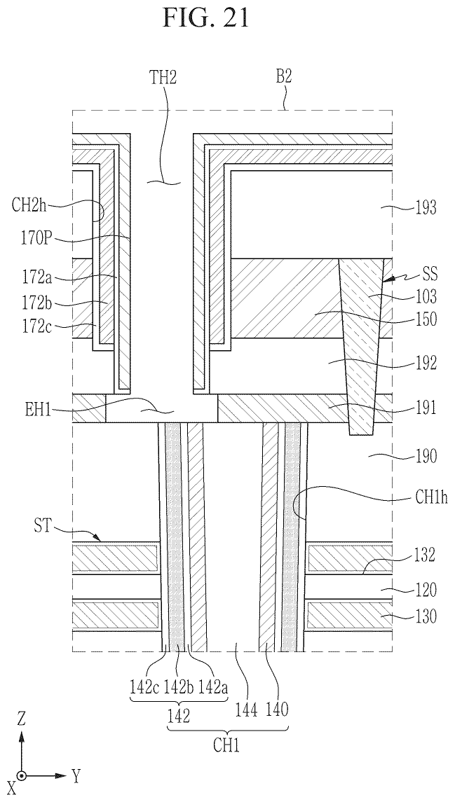

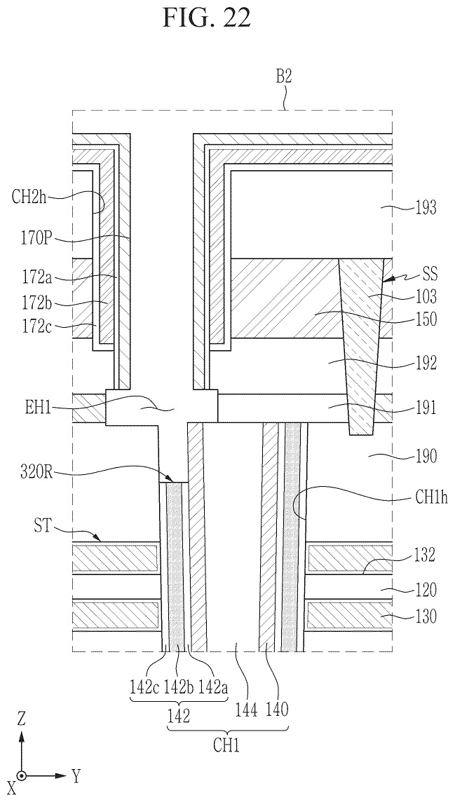

That is, in a case where the second portion 320 and the third portion 330 are formed together, as a first expansion hole (EH1 in FIG. 21 and FIG. 22) and the channel recess 320R have a same width, the second portion 320 and the third portion 330 may completely fill the first expansion hole (EH1 in FIG. 1) and the channel recess 320R. Accordingly, the first channel structure CH1 and the second channel structure CH2 may be stably connected. A description of this will be provided later in a description of a manufacturing method for the semiconductor device 10 with reference to FIG. 12 and following figures.

In an implementation, as illustrated in FIG. 4, the second width W2 in the radial direction from the center CC1 of the first channel structure CH1 of the third portion 330 may be substantially equal to a width of the third portion 330 in the second direction (the direction Y) in a cross section in the second direction (the direction Y) and the third direction (the direction Z). That is, in an implementation, the width of the third portion 330 along the second direction (the direction Y) may be greater than the width of the first ferroelectric layer 142b in the second direction (the direction Y). Furthermore, the width of the third portion 330 along the second direction (the direction Y) may be substantially equal to the second thickness H2 of the second portion 320 in the third direction (the direction Z).

In an implementation, the third portion 330 may have a constant width depending on an aspect ratio thereof. That is, the second width W2 in the radial direction from the center CC1 of the first channel structure CH1 of the third portion 330 may substantially be the same depending on the aspect ratio. However, the present disclosure is not limited thereto, and the third portion 330 may have an inclined side surface that becomes narrower as it approaches the substrate 101 depending on the aspect ratio.

Furthermore, a lower surface of the third portion 330 may be positioned closer to the stacked structure ST than a lower surface of the insulating pattern 191. That is, a distance from an upper surface of the stacked structure ST to the lower surface of the insulating pattern 191 may be greater than a distance from the upper surface of the stacked structure ST to the lower surface of the third portion 330. That is, the lower surface of the third portion 330 may be positioned at a lower level than that of the lower surface of the insulating pattern 191.

In an implementation, the first to third portions 310 to 330 of the second channel layer 300 may be formed integrally through a same process. Specifically, at least a portion of the first portion 310 may be formed integrally with the second portion 320 and the third portion 330 through the same process. As an example, a portion of the first portion 310 may be formed integrally through the same process as that of the second portion 320 and the third portion 330, and a remaining portion of the first portion 310 may be formed through a process separate from that of the second portion 320 and the third portion 330. In this case, the remaining portion of the first portion 310 formed through the separate process may include a same material as that of the portion of the first portion 310. Accordingly, a boundary may not be visible between the first portion 310 and the second portion 320 as illustrated in FIG. 4. However, the present disclosure is not limited thereto, a boundary may be visible between a portion of the first portion 310 and the second portion 320. This will be described later with reference to FIG. 8.

The second dielectric layer 172 according to an implementation may be positioned between the selection gate electrode 150 and the first portion 310 of the second channel layer 300.

As illustrated in FIG. 4, the second dielectric layer 172 of the semiconductor device 100 according to an implementation may include a second channel insulating layer 172a, a second ferroelectric layer 172b, and a second blocking layer 172c sequentially stacked from an outer surface of the first portion 310.

In an implementation, the second dielectric layer 172 may include a similar structure or a same material as that of the first dielectric layer 142. For example, the second channel insulating layer 172a may include a similar structure to and/or a same material as that of the first channel insulating layer 142a. The second ferroelectric layer 172b may include a similar structure to and/or a same material as the first ferroelectric layer 142b. The second blocking layer 172c may include a similar structure to and/or include a same material as that of the first blocking layer 142c.

The second channel insulating layer 172a may surround the first portion 310 of the second channel layer 300. The second channel insulating layer 172a may include various insulating materials. For example, a remaining portion of the upper surface of the second channel insulating layer 172a may be in contact with the insulating pattern 191.

The second ferroelectric layer 172b may surround at least a portion of the second channel insulating layer 172a. The second ferroelectric layer 172b may be disposed between the selection gate electrode 150 and the second channel insulating layer 172a and between the second upper insulating layer 193 and the second channel insulating layer 172a. The second ferroelectric layer 172b may be provided between the second channel insulating layer 172a and the selection gate electrodes 150.

In an implementation, the second ferroelectric layer 172b may include a same material as that of the first ferroelectric layer 142b. The second ferroelectric layer 172b may include a ferroelectric material. A description of the second ferroelectric layer 172b is substantially the same as a description of the first ferroelectric layer 142b and so will be omitted. However, the present disclosure is not limited thereto, and the second ferroelectric layer 172b may include a different material from the first ferroelectric layer 142b.

The second blocking layer 172c may surround the second ferroelectric layer 172b. For example, the second blocking layer 172c may cover outer and lower surfaces of the second ferroelectric layer 172b. The second blocking layer 172c may extend to have a conformal shape along an inner wall of the second channel hole CH2h. The second blocking layer 172c may be positioned to cover the inner wall and a lower surface of the second channel hole CH2h. The second blocking layer 172c may be disposed between the selection gate electrode 150 and the second ferroelectric layer 172b and between the first upper insulating layer 192 and the second ferroelectric layer 172b. The second blocking layer 172c may be provided between the second ferroelectric layer 172b and the gate electrode 130.

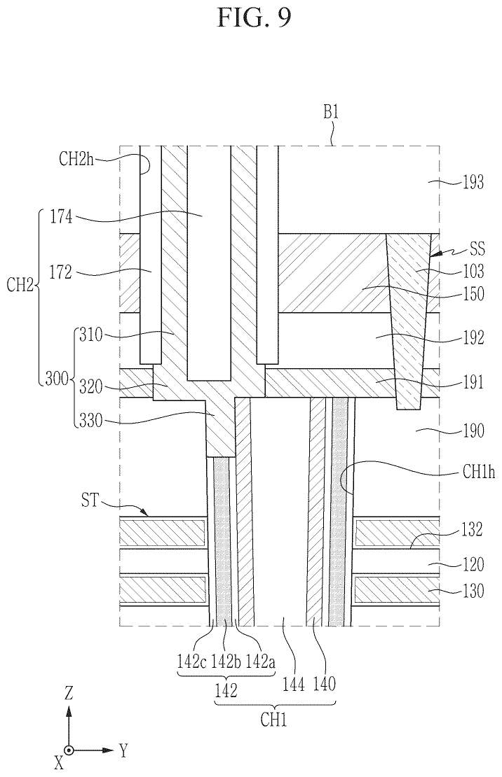

In FIG. 4, a case where the second dielectric layer 172 is a multilayer has been described, but the present disclosure is not limited thereto, and the second dielectric layer 172 may include a different structure or material than that of the first dielectric layer 142. For example, the second dielectric layer 172 may be made as a single layer. This will be described later with reference to FIG. 9.

The third portion 330 of the second channel layer 300 according to an implementation may be in contact with the outer surface 140E of the first channel layer 140, and the second portion 320 of the second channel layer 300 may contact an upper surface of the first channel layer 140. Accordingly, a contact area between the second channel layer 300 and the first channel layer 140 may be increased, and even in a case where at least a portion of the second channel structure CH2 does not overlap with the first channel structure CH1 in the third direction (the direction Z), the contact area between the first channel layer 140 and the second channel layer 300 may be secured. Therefore, the reliability of the semiconductor device 100 may be secured.

Furthermore, in an operation of forming the second portion 320 and the third portion 330, the second width W2 in the radial direction from the center CC1 of the first channel structure CH1 of the third portion 330 may be substantially equal to the second thickness H2 of the second portion 320 in the third direction (the direction Z). Accordingly, in a case where the second portion 320 and the third portion 330 are formed together, the second portion 320 and the third portion 330 may be completely filled in a first expansion hole (‘EH1’ in FIG. 21) and a channel recess (‘320R’ in FIG. 21). In other words, it may be possible to prevent an inside of the first expansion hole (‘EH1’ in FIG. 21) and an inside of the channel recess (‘320R’ in FIG. 21) from not being filled. Accordingly, the first channel structure CH1 and the second channel structure CH2 may be stably connected, and the reliability of the semiconductor device 100 may be secured.

Hereinafter, an example semiconductor device will be described with reference to FIG. 6 and FIG. 9.

FIG. 6 illustrates a cross-sectional view corresponding to a region B1 in FIG. 3, showing the semiconductor device according to some implementations.

Since the implementation illustrated in FIG. 6 is equivalent to the implementation illustrated in FIG. 1 to FIG. 5, a description thereof will be omitted and differences therebetween will be mainly described. In the present implementation, a shape of the second channel insulating layer 172a is different from that of the previous implementation and will be described below.

The memory cell region CELL of the semiconductor device 100 according to an implementation may include a substrate 101, and first and second horizontal conductive layers 102 and 104, a stacked structure ST, a first channel structure CH1, an insulating pattern 191, a selection gate electrode 150, and a second channel structure CH2, disposed on the substrate 101. Herein, the stacked structure ST may include a plurality of gate electrodes 130 and interlayer insulating layers 120 that are alternately stacked. In addition, in an implementation, the second channel layer 300 may include a first portion 310 extending through the selection gate electrode 150, a second portion 320 extending through the insulating pattern 191 and in contact with an upper surface of the first channel layer 140, and a third portion 330 protruding from a lower surface of the second portion 320 and contacting the outer surface 140E of the first channel layer 140.

In the previous implementation, the second channel insulating layer 172a may contact a side surface of the first portion 310 of the second channel layer 300. Furthermore, an entire lower surface of the first portion 310 may be in contact with the upper surface of the second portion 320.

Referring to FIG. 6, the second channel insulating layer 172a according to an implementation may further include a protruding portion 173 extending between the first portion 310 and the second portion 320 of the second channel layer 300.

Specifically, the second channel insulating layer 172a may include a portion covering a side surface of the first portion 310 and a protruding portion 173 extending between the first portion 310 and the second portion 320. The protruding portion 173 may be positioned between an upper surface 310U of the second portion 320 and a lower surface of the first portion 310. The protruding portion 173 may surround a portion of the lower surface of the first portion 310. Accordingly, a portion of the lower surface of the first portion 310 may be in contact with the second channel insulating layer 172a, and a remaining portion of the lower surface of the first portion 310 may be in contact with the second portion 320.

In this case, the upper surface 310U of the second portion 320 may be positioned at substantially a same level as that of the upper surface of the insulating pattern 191. That is, a distance from the upper surface 310U of the second portion 320 to the selection gate electrode 150 may be substantially the same as a distance from the upper surface of the insulating pattern 191 to the selection gate electrode 150.

The protruding portion 173 of the second channel insulating layer 172a may be positioned between the second portion 320 and the first portion 310 of the semiconductor device 100 according to an implementation, and thus the protruding portion 173 may surround a portion of the lower surface of the first portion 310. Accordingly, the remaining portion of the lower surface of the first portion 310 may be in contact with the second portion 320, and the first portion 310 may be electrically connected to the first channel structure CH1 through the second portion 320.

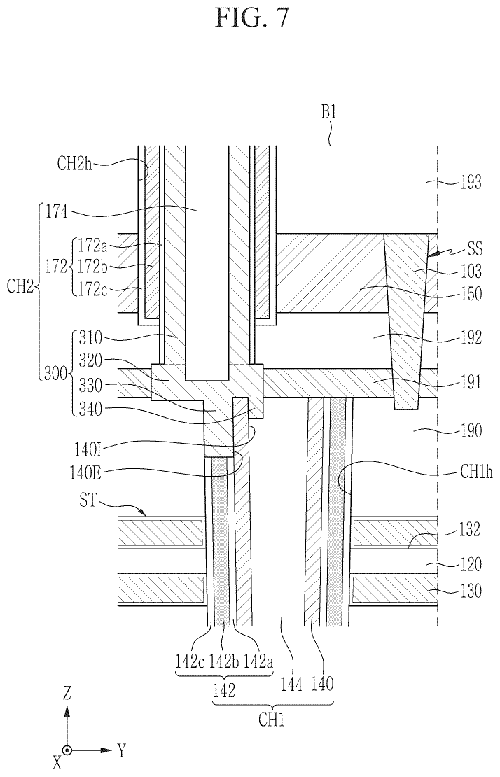

FIG. 7 illustrates a cross-sectional view corresponding to a region B1 in FIG. 3, showing the semiconductor device according to some implementations.

Since the implementation illustrated in FIG. 7 is equivalent to the implementation illustrated in FIG. 1 to FIG. 5, a description thereof will be omitted and differences therebetween will be mainly described. In the present implementation, a shape of the second channel layer 300 is different from that of the previous implementation and will be described below.

The memory cell region CELL of the semiconductor device 100 according to an implementation may include a substrate 101, and first and second horizontal conductive layers 102 and 104, a stacked structure ST, a first channel structure CH1, an insulating pattern 191, a selection gate electrode 150, and a second channel structure CH2, disposed on the substrate 101. Herein, the stacked structure ST may include a plurality of gate electrodes 130 and interlayer insulating layers 120 that are alternately stacked.

In the previous implementation, the second channel layer 300 may include a first portion 310 extending through the selection gate electrode 150, a second portion 320 extending through the insulating pattern 191 and is in contact with an upper surface of the first channel layer 140, and a third portion 330 protruding from a lower surface of the second portion 320 and contacting the outer surface 140E of the first channel layer 140.

Referring to FIG. 7, the second channel layer 300 according to an implementation may further include a fourth portion 340 positioned between the second portion 320 and the first core insulating layer 144.

The fourth portion 340 may protrude from the lower surface of the second portion 320 toward the substrate 101. The fourth portion 340 may be positioned on the first core insulating layer 144. The fourth portion 340 may overlap the first core insulating layer 144 in a third direction (the direction Z).

In an implementation, the fourth portion 340 may be positioned on an inner surface 1401 of the first channel layer 140. For example, the fourth portion 340 may be positioned between the first channel layer 140 and the first core insulating layer 144. The fourth portion 340 may overlap the first channel layer 140 in the horizontal direction (the first direction (the direction X) and/or the second direction (the direction Y)). The fourth portion 340 may be in contact with the inner surface 1401 of the first channel layer 140. Accordingly, the fourth portion 340 may be electrically connected to the first channel layer 140.

In an implementation, the fourth portion 340 may have a constant width. That is, a width of an upper surface of the fourth portion 340 and a width of a lower surface of the fourth portion 340 may be substantially the same. Herein, the width of the fourth portion 340 may be a width in the horizontal direction (the first direction (the direction X) and/or the second direction (the direction Y)).

In the case of the semiconductor device 100 according to an implementation, the third portion 330 of the second channel layer 300 may be in contact with the outer surface 140E of the first channel layer 140, and the second portion 320 of the second channel layer 300 may contact an upper surface of the first channel layer 140. In addition, the fourth portion 340 may be in contact with the inner surface 1401 of the first channel layer 140. Accordingly, a contact area between the second channel layer 300 and the first channel layer 140 may be increased, and even in a case where at least a portion of the second channel structure CH2 does not overlap with the first channel structure CH1 in the third direction (the direction Z), the contact area between the first channel layer 140 and the second channel layer 300 may be secured. Therefore, the reliability of the semiconductor device 100 may be secured.

FIG. 8 illustrates a cross-sectional view corresponding to a region B1 in FIG. 3, showing the semiconductor device according to some implementations.

Since the implementation illustrated in FIG. 8 is equivalent to the implementation illustrated in FIG. 1 to FIG. 5, a description thereof will be omitted and differences therebetween will be mainly described. In the present implementation, a shape of the first portion 310 of the second channel layer 300 is different from that of the previous implementation and will be described below.

The memory cell region CELL of the semiconductor device 100 according to an implementation may include a substrate 101, and first and second horizontal conductive layers 102 and 104, a stacked structure ST, a first channel structure CH1, an insulating pattern 191, a selection gate electrode 150, and a second channel structure CH2, disposed on the substrate 101. Herein, the stacked structure ST may include a plurality of gate electrodes 130 and interlayer insulating layers 120 that are alternately stacked. In addition, in an implementation, the second channel layer 300 may include a first portion 310 extending through the selection gate electrode 150, a second portion 320 extending through the insulating pattern 191 and in contact with an upper surface of the first channel layer 140, and a third portion 330 protruding from a lower surface of the second portion 320 and contacting the outer surface 140E of the first channel layer 140.

In the previous implementation, the first portion 310 of the second channel layer 300 may be made as a single layer.

Referring to FIG. 8, the first portion 310 of the second channel layer 300 according to an implementation may be formed to include multiple layers. For example, the first portion 310 may include a first semiconductor layer 312 and a second semiconductor layer 311.

The first semiconductor layer 312 may be positioned on the second core insulating layer 174. The first semiconductor layer 312 may be positioned between a side surface of the second core insulating layer 174 and an inner surface of the second semiconductor layer 311. The first semiconductor layer 312 may have a planar shape such as an annular shape. A lower surface of the first semiconductor layer 312 may contact an upper surface of the second portion 320 of the second channel layer 300. Accordingly, the first semiconductor layer 312 and the second portion 320 may be electrically connected.

In an implementation, the first semiconductor layer 312 may be connected to the second portion 320 and the third portion 330 to form an integrated body. Specifically, the first semiconductor layer 312 may be formed integrally with the second portion 320 and the third portion 330 through a same process. Accordingly, the first semiconductor layer 312 and the second portion 320 and the first semiconductor layer 312 and the third portion 330 that are formed as a single body may include a same material. For example, the first semiconductor layer 312, the second portion 320, and the third portion 330 may include polycrystalline silicon. Accordingly, a boundary may not be visible between the first semiconductor layer 312 and the second portion 320.

The second semiconductor layer 311 may be positioned on an outer surface of the first semiconductor layer 312. The second semiconductor layer 311 may surround the first semiconductor layer 312. The second semiconductor layer 311 may be positioned between the first semiconductor layer 312 and the second dielectric layer 172. The second semiconductor layer 311 may have a planar shape such as an annular shape. A lower surface of the second semiconductor layer 311 may contact an upper surface of the second portion 320 of the second channel layer 300. Accordingly, the second semiconductor layer 311 and the second portion 320 may be electrically connected.

In an implementation, the second semiconductor layer 311 may include a different material from that of the first semiconductor layer 312. For example, the second semiconductor layer 311 may include a different semiconductor material from that of the first semiconductor layer 312. Accordingly, a boundary may be visible between the second semiconductor layer 311 and the first semiconductor layer 312. This may be due to a process characteristic of forming the second semiconductor layer 311 and the first semiconductor layer 312 in separate processes.

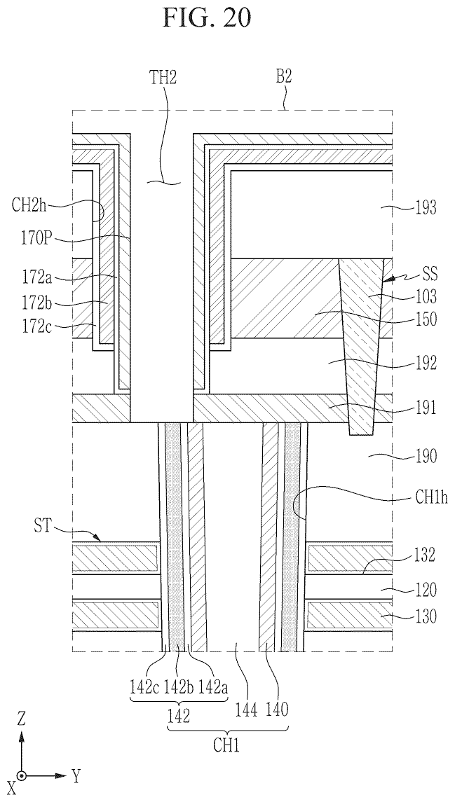

However, the present disclosure is not limited thereto, and although the second semiconductor layer 311 includes a same material as that of the first semiconductor layer 312, a boundary may be visible between the second semiconductor layer 311 and the first semiconductor layer 312. For example, in an operation of forming the second semiconductor layer 311, after forming a material layer made of amorphous silicon in the second through hole (‘TH2’ in FIG. 20), the second semiconductor layer 311 may be formed of polycrystalline silicon by performing an annealing process. In this case, an interface may exist between the second semiconductor layer 311 and the first semiconductor layer 312.

In an implementation, the second semiconductor layer 311 may include a different material from that of the second portion 320 and the third portion 330. For example, the second semiconductor layer 311 may include a semiconductor material different from that of the second portion 320 and the third portion 330. Accordingly, a boundary may be visible between the second semiconductor layer 311 and the second portion 320. This may be due to a process characteristic of forming the second semiconductor layer 311 and the second portion 320 in separate processes.

In summary, a boundary between the first semiconductor layer 312 and the second portion 320 may not be visible, and the boundary may be visible between the second semiconductor layer 311 and the second portion 320.

FIG. 9 illustrates a cross-sectional view corresponding to the region B1 in FIG. 3, showing the semiconductor device according to some implementations.

Since the implementation illustrated in FIG. 9 is equivalent to the implementation illustrated in FIG. 1 to FIG. 5, a description thereof will be omitted and differences therebetween will be mainly described. In the present implementation, a shape of the second dielectric layer 172 is different from that of the previous implementation, and will be described below.

The memory cell region CELL of the semiconductor device 100 according to an implementation may include a substrate 101, and first and second horizontal conductive layers 102 and 104, a stacked structure ST, a first channel structure CH1, an insulating pattern 191, a selection gate electrode 150, and a second channel structure CH2, disposed on the substrate 101. Herein, the stacked structure ST may include a plurality of gate electrodes 130 and interlayer insulating layers 120 that are alternately stacked. In addition, in an implementation, the second channel layer 300 may include a first portion 310 extending through the selection gate electrode 150, a second portion 320 extending through the insulating pattern 191 and in contact with an upper surface of the first channel layer 140, and a third portion 330 protruding from a lower surface of the second portion 320 and contacting the outer surface 140E of the first channel layer 140.

In the previous implementation, the second dielectric layer 172 may include a second channel insulating layer 172a, a second ferroelectric layer 172b, and a second blocking layer 172c sequentially stacked from an outer surface of the first portion 310 of the second channel layer 300.

Referring to FIG. 9, the second dielectric layer 172 according to an implementation may be made as a single layer.

The second dielectric layer 172 may be positioned between the selection gate electrode 150 and the first portion 310 of the second channel layer 300. The second dielectric layer 172 may surround the first portion 310. The second dielectric layer 172 may extend to have a conformal shape along an inner wall of the second channel hole CH2h. The second dielectric layer 172 may be positioned to cover an inner wall of the second channel hole CH2h. The second dielectric layer 172 may be positioned between the selection gate electrode 150 and the first portion 310, between the second upper insulating layer 193 and the first portion 310, and between the first upper insulating layer 192 and the first portion 310.

For example, the second dielectric layer 172 may include a silicon oxide, a silicon nitride, a silicon oxynitride, or a combination thereof. However, the present disclosure is not limited thereto.

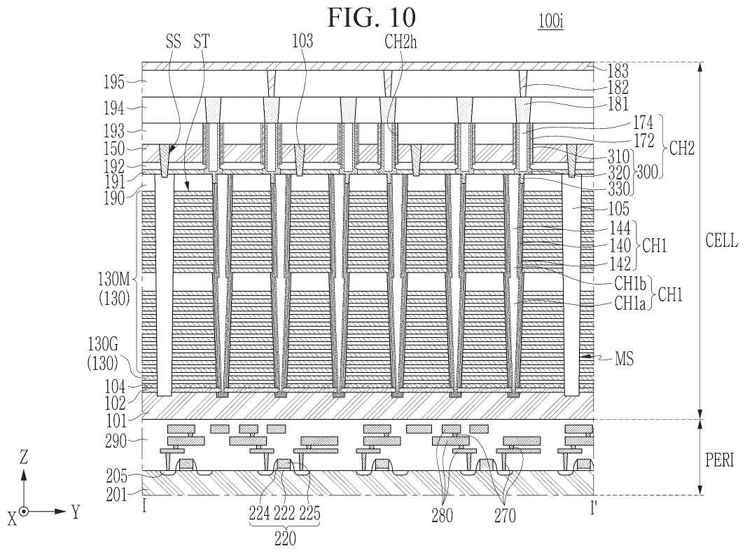

Hereinafter, another implementation of a semiconductor device will be described with reference to FIG. 10. In the following implementations, same reference numerals refer to components identical to those of the previously described implementations, and redundant descriptions will be omitted or simplified, and the description will focus on differences.

FIG. 10 illustrates a cross-sectional view showing a semiconductor device according to some implementations. FIG. 10 illustrates a cross-sectional view corresponding to a portion taken along a line I-I′ of FIG. 1.

Referring to FIG. 10, in the semiconductor device 100i, a stacked structure of the gate electrodes 130 may include vertically stacked lower and upper stacked structures, and the first channel structure CH1 may include vertically stacked lower and upper channel structures CH1a and CH1b. This structure of the first channel structure CH1 may be introduced to stably form the first channel structure CH1 in a case where a number of gate electrodes 130 stacked is relatively large. According to implementations, a number of stacked first channel structures may vary.

The first channel structure CH1 may have a shape in which the lower channel structure CH1a and the upper channel structure CH1b are connected and may also have a bent portion due to a difference in width in a connection region. The first channel layer 140, the first dielectric layer 142, and the first core insulating layer 144 may be connected to each other between the lower channel structure CH1a and the upper channel structure CH1b.

A relatively thick upper interlayer insulating layer may be disposed on a lower stacked structure. However, the present disclosure is not limited thereto, and a shape of the upper interlayer insulating layer may vary in various implementations.

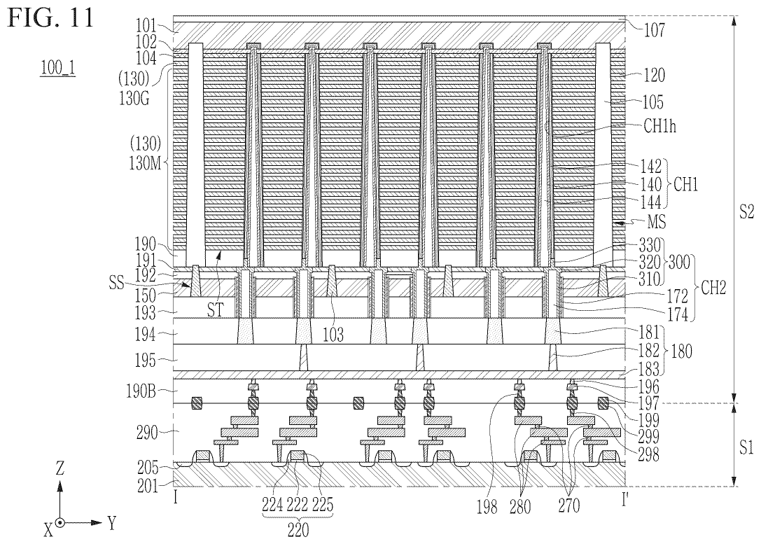

Hereinafter, another implementation of a semiconductor device will be described with reference to FIG. 11. In the following implementations, same reference numerals refer to components identical to those of the previously described implementations, and redundant descriptions will be omitted or simplified, and description will focus on differences.

FIG. 11 illustrates a cross-sectional view showing a semiconductor device according to some implementations. FIG. 11 illustrates a cross-sectional view corresponding to a portion taken along a line I-I′ of FIG. 1.

According to the implementation illustrated in FIG. 11, the semiconductor device 100_1 may include a first structure S1 and a second structure S2 bonded using a wafer bonding method.

Regarding the first structure S1, the description of the peripheral circuit region PERI described above with reference to FIG. 3 may be applied substantially in the same way. However, the first structure S1 may further include first bonding vias 298 and first bonding pads 299, which are a bonding structure.

Specifically, the first bonding vias 298 may be positioned at an upper portion of the uppermost circuit wire lines 280 to be connected to the circuit wire lines 280. At least some of the first bonding pads 299 may be connected to the first bonding vias 298 on the first bonding vias 298. The first bonding pads 299 may be connected to the second bonding pads 199 of the second structure S2. The first bonding pads 299, together with the second bonding pads 199, may provide an electrical connection path for bonding the first structure S1 and the second structure S2. The first bonding vias 298 and the first bonding pads 299 may include a conductive material, e.g., copper (Cu). However, the present disclosure is not limited thereto.

In a case where there is no separate description for the second structure S2, contents described with reference to FIGS. 1 to 10 may be applied substantially in the same manner except that the substrate 101 of the second structure S2 and the first channel structure CH1 are positioned at an upper side, and the second channel structure CH2 is positioned at a lower side,

An upper wiring structure of the second structure S2 may further include a conductive via 196 and a conductive line 197 connected to the upper wire 183. In FIG. 11, a plurality of conductive lines 197 are illustrated to be positioned at a same level, but the present disclosure is not limited thereto, and in some implementations, unlike what is illustrated in FIG. 11, the conductive lines 197 may include a plurality of conductive lines positioned at different levels.

Furthermore, the second structure S2 may further include second bonding vias 198 and second bonding pads 199, which are a bonding structure. The second structure S2 may further include a protective layer 107 covering an upper surface of the substrate 101.

The second bonding vias 198 and the second bonding pads 199 may be positioned at a lower portion of the lowest conductive line 197. The second bonding vias 198 may be connected to the conductive line 197 and the second bonding pads 199, and the second bonding pads 199 may be bonded to the first bonding pads 299 of the first structure S1. The second bonding vias 198 and the second bonding pads 199 may include a conductive material, e.g., copper (Cu). However, the present disclosure is not limited thereto.

The first structure S1 and the second structure S2 may be bonded by copper (Cu)-copper (Cu) bonding using the first bonding pads 299 and the second bonding pads 199. In addition to the copper (Cu)-copper (Cu) bonding, the first structure S1 and the second structure S2 may be additionally bonded by dielectric-dielectric bonding. The dielectric-dielectric bonding may be performed by dielectric layers which form a part of each of the peripheral region insulating layer 290 and the cell area insulating layer 190B, and surround each of the first bonding pads 299 and the second bonding pads 199. As a result, the first structure S1 and the second structure S2 may be bonded without a separate adhesive layer.

An example manufacturing method for an example semiconductor device will now be described with reference to FIG. 12 to FIG. 24.

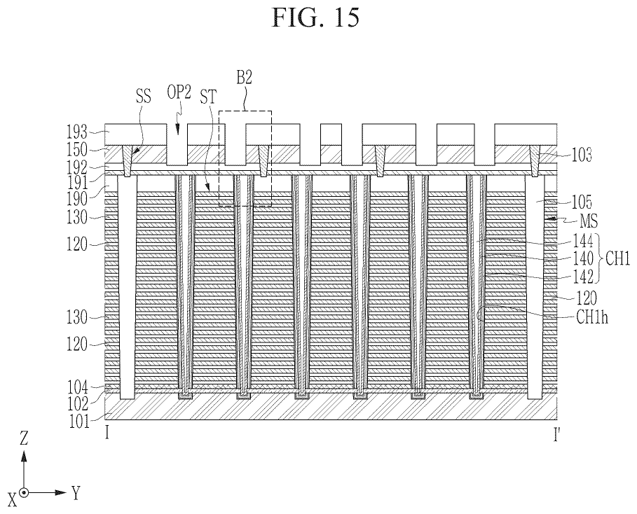

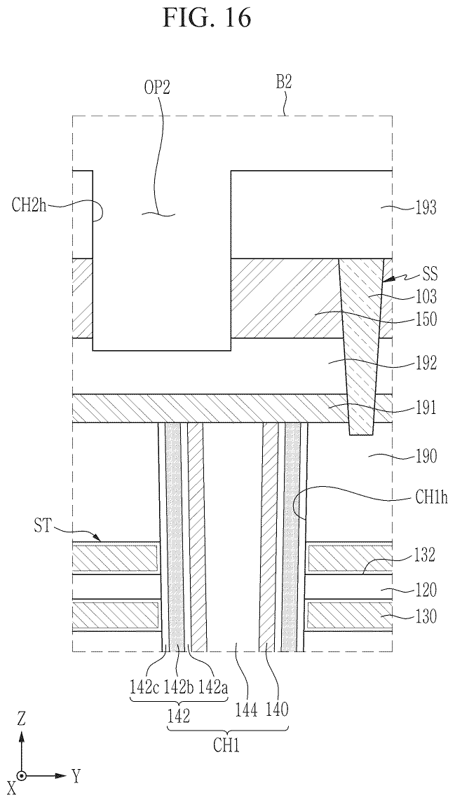

FIG. 12 to FIG. 15 illustrate cross-sectional views showing a manufacturing method for a semiconductor device according to implementations. FIG. 16 to FIG. 24 illustrate cross-sectional views corresponding to a region B2 in FIG. 15, showing an example manufacturing method for a semiconductor device. Hereinafter, the same reference numerals refer to components identical to those previously described, and redundant descriptions will be omitted or simplified, and the description will focus on differences.

Referring to FIG. 12, first, a preliminary laminated structure ST_P may be formed by forming horizontal sacrificial layers 110 and a second horizontal conductive layer 104 on the substrate 101, and alternately stacking sacrificial insulating layers 118 and interlayer insulating layers 120.

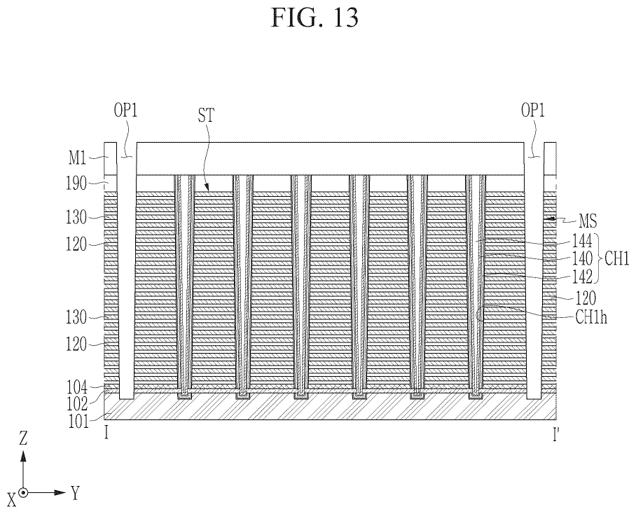

Although not illustrated in FIG. 12, the horizontal sacrificial layers 110 may include first to third horizontal sacrificial layers sequentially disposed on the substrate 101. In this case, the second horizontal sacrificial layer may include a different material from the first horizontal sacrificial layer and the third horizontal sacrificial layer. The horizontal sacrificial layers 110 may be layers that are replaced with the first horizontal conductive layer (see ‘102’ in FIG. 13) through a subsequent process. For example, the first and third horizontal sacrificial layers may be made of a same material as that of the interlayer insulating layers 120, and the second horizontal sacrificial layer may be made of a same material as that of the sacrificial insulating layers 118. The second horizontal conductive layer 104 may be disposed on the horizontal sacrificial layers 110.

Furthermore, the sacrificial insulating layers 118 may be layers that are partially replaced with first gate electrodes (see ‘130’ in FIG. 13) through a subsequent process. The sacrificial insulating layers 118 may be made of a different material from that of the interlayer insulating layers 120. The sacrificial insulating layers 118 may include a material that has an etch selectivity with respect to the interlayer insulating layers 120. For example, the interlayer insulating layer 120 may made of at least one of a silicon oxide or a silicon nitride, and the sacrificial insulating layers 118 may be made of a different material from the interlayer insulating layer 120 selected from silicon, a silicon oxide, a silicon carbide, and a silicon nitride. Thicknesses of the interlayer insulating layers 120 and the sacrificial insulating layers 118 and the number of films constituting them may vary from those illustrated.

Subsequently, the first channel structure CH1 extending through a preliminary stacked structure ST_P may be formed.

First, the cell region insulating layer 190 may be formed to cover the preliminary stack structure ST_P including the sacrificial insulating layers 118 and the interlayer insulating layers 120. Next, an opening corresponding to the first channel hole CH1h extending through the cell region insulating layer 190 and the preliminary stack structure ST_P may be formed. The first channel hole CH1h may be formed by etching the sacrificial insulating layers 118 and the interlayer insulating layers 120 included in the preliminary stack structure ST_P using a mask layer. Due to a height of the preliminary stacked structure ST_P, a sidewall of the first channel hole CH1h may not be perpendicular to an upper surface of the substrate 101. The first channel hole CH1h may be formed to include a recess into a portion of the substrate 101.

Subsequently, the first dielectric layer 142, the first channel layer 140, and the first core insulating layer 144 may be sequentially formed in the first channel hole CH1h. The first dielectric layer 142 may be formed to have a uniform thickness using an atomic layer deposition (ALD) process or a chemical vapor deposition (CVD) process.

The first channel layer 140 may be disposed on the first dielectric layer 142 within the first channel hole CH1h. The first core insulating layer 144 is formed to fill an inside of the first channel structure CH1 and may be an insulating material.

Referring to FIG. 13, forming first openings OP1 extending through the preliminary stacked structure ST_P in regions corresponding to the separation regions (see ‘MS’ in FIG. 15), and a first horizontal conductive layer 102 and a plurality of gate electrodes 130 may be formed.

First, a mask layer M1 including a first opening OP1 may be disposed on the first channel structure CH1. The first opening OP1 may be formed to extend through the preliminary stacked structure ST_P including the sacrificial insulating layers 118 and the interlayer insulating layers 120, the second horizontal conductive layer 104, and the horizontal sacrificial layer 110. The first opening OP1 may be formed to extend in the third direction (the direction Z). Accordingly, the preliminary stacked structure ST_P may be separated to form the stacked structure ST.

Next, the horizontal sacrificial layers 110 exposed by the first opening OP1 may be removed. The horizontal sacrificial layers 110 may be removed by, e.g., a wet etching process. In a process of removing the horizontal sacrificial layers 110, a portion of the first dielectric layer 142 exposed in a region from which the horizontal sacrificial layers 110 were removed may also be removed. Thereafter, the first horizontal conductive layer 102 may be formed in a space where the horizontal sacrificial layers 110 have been removed.

Next, the sacrificial insulating layer 118 exposed by the first opening OP1 may be removed to form tunnel portions, and a plurality of gate electrodes 130 may be formed by burying a conductive material in the tunnel portions. The tunnel portions may be formed, e.g., through a wet etching process that selectively removes the sacrificial insulating layers 118 with respect to the interlayer insulating layers 120.

The conductive material forming the gate electrodes 130 may include a metal, polycrystalline silicon, or a metal silicide material. In this case, before forming the gate electrodes 130, a dielectric layer with a conformal thickness may be deposited to form a gate dielectric layer (see ‘132’ in FIG. 4) together.

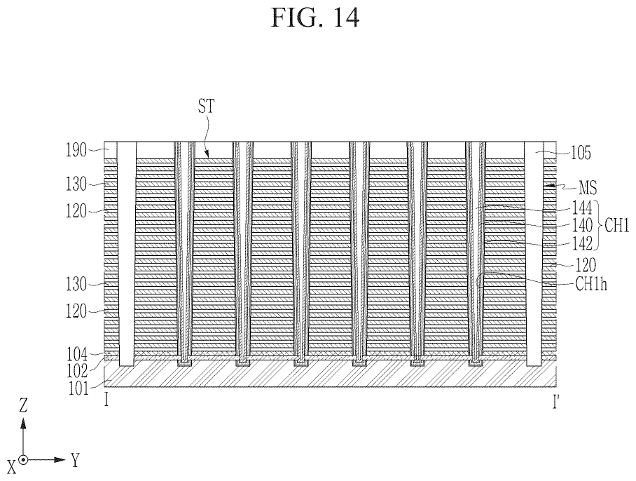

Referring to FIG. 14, a separation insulating layer 105 may be formed in the separation regions MS.

A process of forming the separation insulating layer 105 may be performed by filling the first openings OP1 with an insulating material and then performing a planarization process to remove the mask layer M1 and the insulating material. The insulating material may include a silicon oxide, a silicon nitride, or a silicon oxynitride. However, the present disclosure is not limited thereto, and in some implementations, the first openings OP1 may be filled with a conductive material along with the insulating material.

The planarization process may be performed such that an upper surface of the separation insulating layer 105 in the separation regions MS is positioned at substantially a same level as that of an upper surface of the first channel structure CH1.

Next, referring to FIGS. 15 and 16, first, the insulating pattern 191, the upper separation insulating layer 103, and the selection gate electrode 150 may be formed.

The insulating pattern 191, the first upper insulating layer 192, and the selection gate electrode 150 may be sequentially positioned on the separation regions MS and the cell region insulating layer 190 through a deposition process. Subsequently, the upper separation insulating layer 103 may be formed in the upper separation region SS, and the second upper insulating layer 193 may be formed through a deposition process.

The insulating pattern 191 may extend in the first direction (the direction X) and the second direction (the direction Y). The insulating pattern 191 may have an integrated structure in which portions excluding the second opening OP2 are connected. Furthermore, the insulating pattern 191 may include a material different from the cell region insulating layer 190 and/or the first upper insulating layer 192. For example, the insulating pattern 191 may include a material having an etch selectivity with respect to the cell region insulating layer 190 and the first upper insulating layer 192. Furthermore, the insulating pattern 191 may include a material having an etch selectivity with respect to the first channel structure CH1 and the cell region insulating layer 190.

The selection gate electrode 150 may be formed by depositing a conductive material, e.g., doped polycrystalline silicon. The selection gate electrode 150 may be formed to have a thickness that is greater than a thickness of each of the gate electrodes 130, but the present disclosure is not limited thereto.

Next, a region corresponding to the upper separation region SS is formed by forming trenches exposing the first upper insulating layer 192 through the selection gate electrode 150 and the insulating pattern 191, and after depositing an insulating material in the trenches, the upper isolation insulating layer 103 may be formed by performing a planarization process.

Subsequently, second openings OP2 extending through the second upper insulating layer 193 and corresponding to the second channel holes Ch2h may be formed by performing a patterning process using the second upper insulating layer 193 as a mask. Accordingly, the second openings OP2 may expose the first upper insulating layer 192. The second openings OP2 may include a portion that overlaps and a portion that does not overlap the first channel structure CH1 in a plan view.

In a process of forming the second openings OP2, a portion of the first upper insulating layer 192 may be removed together therewith. That is, the first upper insulating layer 192 may include a portion recessed by the second openings OP2, but the present disclosure is not limited thereto. In some implementations, the first upper insulating layer 192 may not be removed and an upper surface of the first upper insulating layer 192 may be exposed.

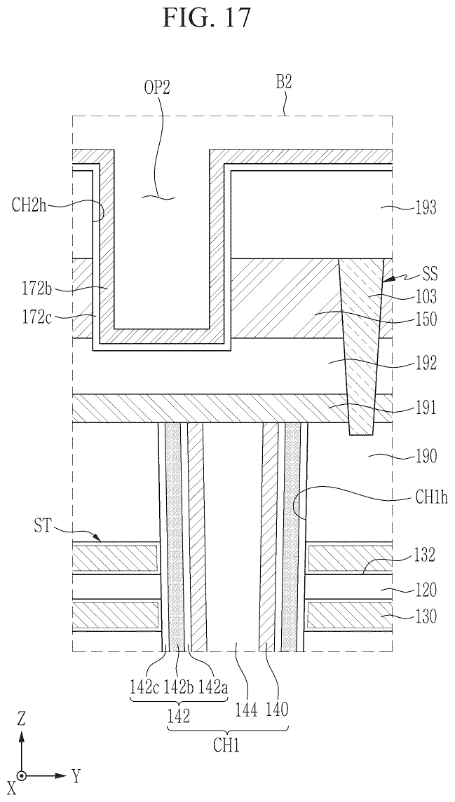

Referring to FIG. 17, the second blocking layer 172c and the second ferroelectric layer 172b may be sequentially formed within the second openings OP2.

Specifically, a second blocking layer 172c and a second ferroelectric layer 172b conformally covering an upper surface of the second upper insulating layer 193, and inner walls and bottom surfaces of the second openings OP2 may be formed by performing the deposition process sequentially.

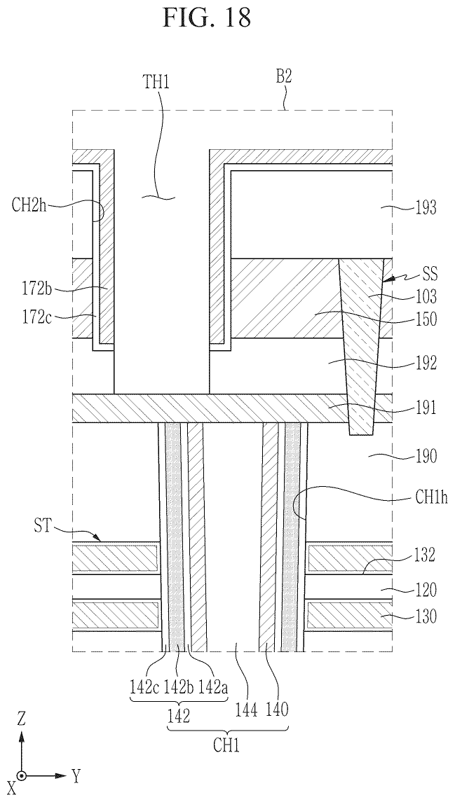

Referring to FIG. 18, a first through hole TH1 extending downward from a bottom surface of the second opening OP2 may be formed. The first through hole TH1 may be formed by performing an etch-back process on the second opening OP2 to expose the insulating pattern 191.

As the etch back process is performed, the second blocking layer 172c sequentially positioned on the bottom surface of the second opening OP2, and a portion of the first upper insulating layer 192 positioned on the bottom surface of the second opening OP2 along with the second ferroelectric layer 172b may be removed. Accordingly, the insulating pattern 191 may be exposed.

In this case, as described above, the insulating pattern 191 may include a material that has etch selectivity with respect to the first upper insulating layer 192, so the insulating pattern 191 may not be removed during the etch back process. However, the present disclosure is not limited thereto, while the etch back process is in progress, a portion of the insulating pattern 191 may be removed together.

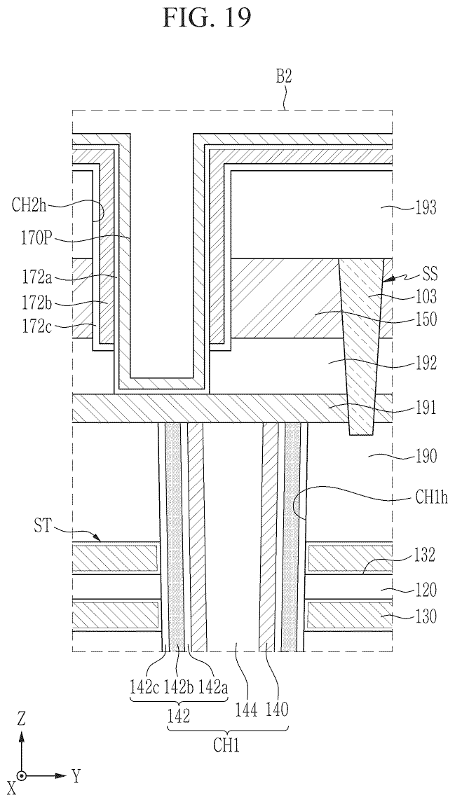

Referring to FIG. 19, the second channel insulating layer 172a and a preliminary channel layer 170P may be sequentially formed in the first through hole TH1.

Specifically, the deposition process may be sequentially performed to form the second channel insulating layer 172a, which conformally covers a side surface of the second ferroelectric layer 172b, a side surface of the first upper insulating layer 192, and the upper surface of the insulating pattern 191, and then the preliminary channel layer 170P may be formed. The preliminary channel layer 170P may include amorphous silicon or polycrystalline silicon. Herein, the preliminary channel layer 170P may be a portion of the first portion 310 of the second channel layer 300 formed in a later process.

Referring to FIG. 20, a second through hole TH2 extending below the bottom surface of the first through hole TH1 may be formed.

The second through hole TH2 may be formed by performing an etching process on the first through hole TH1 to expose the first dielectric layer 142. The etching process for forming the second through hole TH2 may be dry etching, but the present disclosure is not limited thereto. As the etching process is performed, a lower surface of the preliminary channel layer 170P, a lower surface of the second channel insulating layer 172a, and at least a portion of the insulating pattern 191 may be removed. Accordingly, a side surface of the insulating pattern 191 and an upper surface of the first dielectric layer 142 may be exposed.

Referring to FIG. 21, the side surface of the insulating pattern 191 exposed by the second through hole TH2 may be etched to form a first expansion hole EH1.

The first expansion hole EH1 may extend in the horizontal direction (the first direction (the direction X) and/or the second direction (the direction Y)) within the insulating pattern 191. For example, the first expansion hole EH1 may be formed to have a circular shape in a plan view. Accordingly, an upper surface of the first dielectric layer 142, an upper surface of the first channel layer 140, an upper surface of the first core insulating layer 144, and an upper surface of the cell region insulating layer 190 may be exposed.

A process of forming the first expansion hole EH1 may be performed using a wet etching process. In this case, as described above, the insulating pattern 191 may include a material having an etch selectivity with respect to the first channel structure CH1 and the cell region insulating layer 190. Accordingly, in the process of forming the first expansion hole EH1 by removing a portion of the insulating pattern 191, the first dielectric layer 142, the first channel layer 140, the first core insulating layer 144, and the cell region insulating layer 190 may be prevented from being etched.

Referring to FIG. 22, a portion of the first dielectric layer 142 exposed by the first expansion hole EH1 may be etched to form a channel recess 320R.

Specifically, a portion of the first ferroelectric layer 142b exposed by the first expansion hole EH1 may be etched. A process of etching the first ferroelectric layer 142b may be performed using wet etching, but the present disclosure is not limited thereto. The first ferroelectric layer 142b may include a material having an etch selectivity with respect to the insulating pattern 191. The first ferroelectric layer 142b may include a material having an etch selectivity with respect to the cell region insulating layer 190. Accordingly, while a portion of the first ferroelectric layer 142b is etched, the insulating pattern 191 and the cell region insulating layer 190 may not be etched.

In this case, in a process of etching a portion of the first ferroelectric layer 142b, a portion of the first blocking layer 142c adjacent to the first ferroelectric layer 142b and a portion of the first channel insulating layer 142a may be etched together. A length along the third direction (the direction Z) in which the first blocking layer 142c and the first channel insulating layer 142a are etched may be substantially equal to a length along the third direction (the direction Z) in which the first ferroelectric layer 142b is etched. That is, the upper surface of the first blocking layer 142c and the upper surface of the first channel insulating layer 142a may be positioned at substantially a same level as the upper surface of the first ferroelectric layer 142b.

Accordingly, a portion of the first dielectric layer 142 may be etched to form a channel recess 320R. The channel recess 320R may extend along a circumferential direction of the first channel structure CH1. An outer surface of the first channel layer 140, the side surface of the cell region insulating layer 190, and the upper surface of the first dielectric layer 142 may be exposed by the channel recess 320R. Accordingly, in an implementation, the upper surface of the first channel layer 140 may be exposed by the first expansion hole EH1, and the outer surface 140E of the first channel layer 140 may be exposed by the channel recess 320R. That is, an area where the first channel layer 140 is exposed may increase.

In an implementation, the channel recess 320R may extend along a circumferential direction of the first channel structure CH1. For example, the channel recess 320R may extend along the circumferential direction of the first channel structure CH1 on the outer surface 140E of the first channel layer 140 in a plan view. Accordingly, at least a portion of the channel recess 320R may overlap the first expansion hole EH1 in the third direction (the direction Z). For example, at least a portion of the channel recess 320R may overlap the first expansion hole EH1 in the third direction (the direction Z), and a remaining portion of the channel recess 320R may not overlap with the first expansion hole EH1 in the third direction (the direction Z). However, the present disclosure is not limited thereto, and for example, the channel recess 320R may completely overlap the first expansion hole EH1 in the third direction (the direction Z).

Furthermore, as a portion of the first dielectric layer 142 is etched, at least a portion of the cell region insulating layer 190 exposed by the first expansion hole EH1 may be etched also. Furthermore, at least a portion of the second blocking layer 172c exposed by the first expansion hole EH1 may be etched also. Accordingly, a lower surface of the preliminary channel layer 170P may be exposed. Furthermore, a thickness of the first expansion hole EH1 along the third direction (the direction Z) may be greater than a thickness of the insulating pattern 191 along the third direction (the direction Z). However, the present disclosure is not limited thereto, and for example, at least a portion of the second blocking layer 172c exposed by the first expansion hole EH1 may not be etched. Furthermore, the thickness of the first expansion hole EH1 along the third direction (the direction Z) may be substantially equivalent to the thickness of the insulating pattern 191 along the third direction (the direction Z).

In an implementation, a width of the channel recess 320R in the radial direction from a center of the first channel structure CH1 may be substantially equal to the thickness of the first expansion hole EH1 in the third direction (the direction Z). Accordingly, the width of the channel recess 320R in the radial direction from the center of the first channel structure CH1 may be greater than the thickness of the insulating pattern 191 in the third direction (the direction Z). However, the present disclosure is not limited thereto, and the width along the radial direction from the center CC1 of the first channel structure CH1 of the channel recess 320R may be greater than the thickness of the first expansion hole EH1 along the third direction (the direction Z).

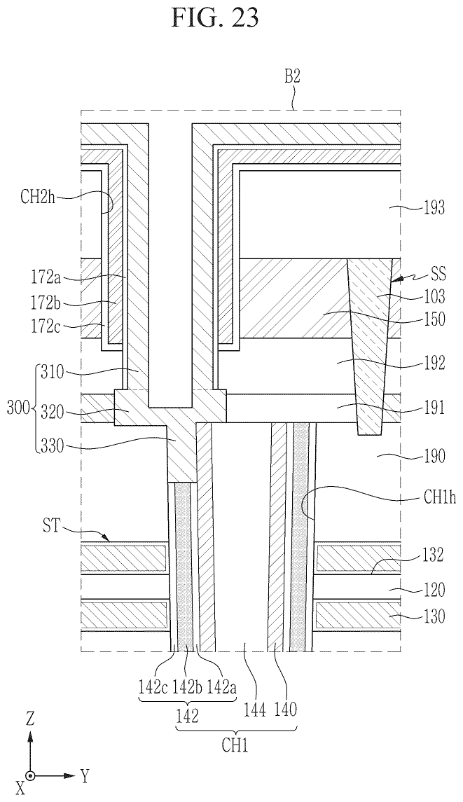

Referring to FIG. 23, the second channel layer 300 may be formed within the first expansion hole EH1 and the channel recess 320R.

Specifically, the third portion 330 of the second channel layer 300 may be formed within the channel recess 320R, and the second portion 320 of the second channel layer 300 may be formed within the first expansion hole EH1.

The third portion 330 may be formed conformally along an inner wall of the channel recess 320R. Furthermore, the second portion 320 may be formed conformally along an inner side wall of the first expansion hole EH1. In this case, formation rates of the second portion 320 and the third portion 330 may be substantially the same. For example, a rate at which the second portion 320 is positioned on the side surface of the insulating pattern 191 may be substantially the same as a rate at which the third portion 330 is positioned on the upper surface of the first dielectric layer 142. Furthermore, a rate at which the second portion 320 is positioned on the upper surface of the cell region insulating layer 190 may be substantially the same as a rate at which the third portion 330 is positioned on the side surface of the cell region insulating layer 190. Herein, the rates at which the second portion 320 and the third portion 330 are formed may indicate a deposition rate of a material layer constituting the second portion 320 and the third portion 330.

In an implementation, as described above, a width of the channel recess 320R in the radial direction from a center of the first channel structure CH1 may be substantially equal to the thickness of the first expansion hole EH1 in the third direction (the direction Z). Thus, rates at which the second channel layer 300 is formed in the first expansion hole EH1 and the channel recess 320R may be the same, so the second channel layer 300 may completely fill the first expansion hole EH1 and the channel recess 320R. As a result, it may be possible to prevent portions of an inside of the first expansion hole EH1 and an inside of the channel recess 320R from not being filled.

In an implementation, a width of the third portion 330 in the radial direction from a center of the first channel structure CH1 may be substantially equal to a thickness of the second portion 320 in the third direction (the direction Z). Accordingly, the width of the third portion 330 in the radial direction from the center of the first channel structure CH1 may be greater than the thickness of the insulating pattern 191 in the third direction (the direction Z). However, the present disclosure is not limited thereto, and the width of the third portion 330 in the radial direction from a center of the first channel structure CH1 may be greater than the thickness of the second portion 320 in the third direction (the direction Z).

Meanwhile, in a process of forming the second channel layer 300, the first portion 310 extending along an inner side wall of the second channel hole CH2h may also be formed. The first portion 310 may be formed conformally along the inner wall of the second channel hole CH2h. For example, the first portion 310 may be formed by forming a channel material layer along an inner wall of the preliminary channel layer 170P. Accordingly, the first to third portions 310 to 330 of the second channel layer 300 may be formed.

In an implementation, the first portion 310 and the preliminary channel layer 170P may include a same material. For example, the first portion 310 and the preliminary channel layer 170P may each include a semiconductor material such as polycrystalline silicon, and the semiconductor material may be an undoped material or a material containing p-type or n-type impurities. The first portion 310 and the preliminary channel layer 170P may include the same material, and thus a boundary may not be visible between the first portion 310 and the preliminary channel layer 170P.

However, the present disclosure is not limited thereto, and a boundary may be visible between the first portion 310 and the preliminary channel layer 170P. For example, the first portion 310 and the preliminary channel layer 170P may include different materials, and thus a boundary may be visible between the first portion 310 and the preliminary channel layer 170P, as in the implementation of FIG. 8. Alternatively, although the first portion 310 and the preliminary channel layer 170P include the same material, a boundary may be visible between the first portion 310 and the preliminary channel layer 170P.

Furthermore, the first portion 310 may include a same material as that of the second portion 320 and the third portion 330. The preliminary channel layer 170P may include a same material as that of the second portion 320 and the third portion 330. Accordingly, boundaries may not be visible between the first portion 310 and the second portion 320 and between the preliminary channel layer 170P and the second portion 320. However, the present disclosure is not limited thereto, and as in the implementation of FIG. 8, the preliminary channel layer 170P may include a different material from the second portion 320, and thus a boundary may be visible between the preliminary channel layer 170P and the second portion 320.

In an implementation, the first portion 310 may be integrally formed by a same deposition process as that of the second portion 320 and the third portion 330, but the present disclosure is not limited thereto, and in some implementations, the first portion 310 may be formed through a plurality of deposition processes using different conductive materials from that of the second portion 320 and the third portion 330.

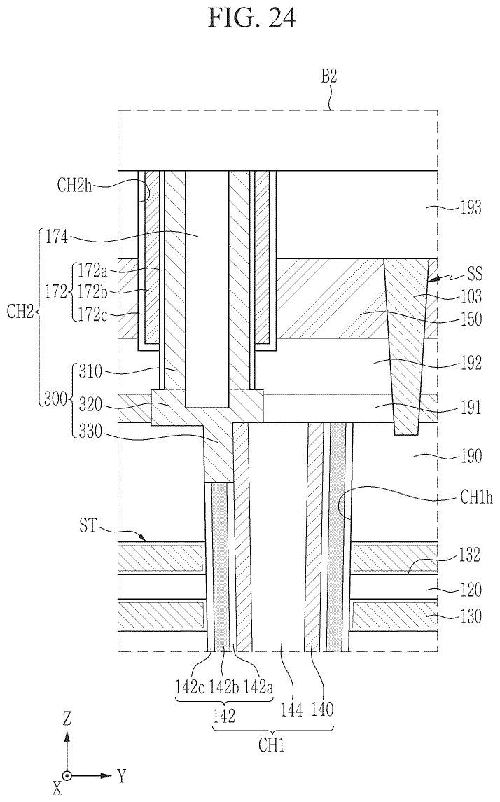

Referring to FIG. 24, first, a second buried insulating layer 174 may be formed in the second through hole TH2.

Specifically, the second buried insulating layer 174 may be formed by filling an insulating material in the second through hole TH2 and then performing a planarization process. In a planarization process step, portions of the second blocking layer 172c, the second ferroelectric layer 172b, and the second channel layer 300 sequentially stacked on the upper surface of the second upper insulating layer 193 may be removed along with insulating materials. Accordingly, the second blocking layer 172c, the second ferroelectric layer 172b, the second channel insulating layer 172a, and the second channel layer 300 may be formed.

Referring further to FIG. 3, the third upper insulating layer 194 covering the second channel structure CH2 may be formed. Next, the stud 181 may be formed through the third upper insulating layer 194 to be in contact with the second channel structure CH2. Finally, the fourth upper insulating layer 195 covering the third upper insulating layer 194 may be formed. Accordingly, the semiconductor device 100 illustrated in FIG. 3 may be formed by forming a contact plug 182 that extends through the fourth upper insulating layer 195 to contact the stud 181, and forming an upper wiring 183 on the contact plug 182.

The third portion 330 of the second channel layer 300 according to an implementation may be in contact with the outer surface 140E of the first channel layer 140, and the second portion 320 of the second channel layer 300 may contact an upper surface of the first channel layer 140. Accordingly, a contact area between the second channel layer 300 and the first channel layer 140 may be increased, and even in a case where at least a portion of the second channel structure CH2 does not overlap with the first channel structure CH1 in the third direction (the direction Z), the contact area between the first channel layer 140 and the second channel layer 300 may be secured. Therefore, the reliability of the semiconductor device 100 may be secured.

Furthermore, in an operation of forming the second portion 320 and the third portion 330, the second width W2 in the radial direction from the center CC1 of the first channel structure CH1 of the third portion 330 may be substantially equal to the second thickness H2 of the second portion 320 in the third direction (the direction Z). In other words, the first expansion hole EH1 and the channel recess 320R may have a same width. Accordingly, in a case where the second portion 320 and the third portion 330 are formed together, the second portion 320 and the third portion 330 may be completely filled in the first expansion hole EH1 and the channel recess 320R. That is, it may be possible to prevent portions of an inside of the first expansion hole EH1 and an inside of the channel recess 320R from not being filled. Accordingly, the first channel structure CH1 and the second channel structure CH2 may be stably connected by the second channel layer 300, and the reliability of the semiconductor device 100 may be secured.

Hereinafter, an example of an electronic system including the semiconductor device described above will be described in detail with reference to FIGS. 25 to 28.

FIG. 25 schematically illustrates an electronic system including a semiconductor device according to some implementations.

Referring to FIG. 25, the electronic system 1000 according to some implementations may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device including one or the plurality of semiconductor devices 1100, a universal serial bus (USB), a computing system, a medical device, or a communication device.

The semiconductor device 1100 may be a non-volatile memory device, and may be, for example, a NAND flash memory device described with reference to FIG. 1 to FIG. 10. The semiconductor device 1100 may include a first structure 1100F and a second structure 1100S on the first structure 1100F. In some implementations, the first structure 1100F may be positioned next to the second structure 1100S. The first structure 1100F may be a peripheral circuit structure including a decoder circuit 1110, a page buffer 1120, and a logic circuit 1130. The second structure 1100S may be a memory cell structure including a bitline BL, a common source line CSL, a word line WL, first and second gate upper lines UL1 and UL2, and first and second gate lower lines LL1 and LL2, and a memory cell string CSTR between the bitline BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2 and the upper transistors UT1 and UT2. A number of lower transistors LT1 and LT2 and a number of upper transistors UT1 and UT2 may be variously modified according to another implementation.

In some implementations, the lower transistors LT1 and LT2 may include ground selective transistors, and the upper transistors UT1 and UT2 may include string selective transistors. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connecting wire 1115 extending from the first structure 1100F to the second structure 1100S. The bitline BL may be electrically connected to the page buffer 1120 through a second connecting wire 1125 extending to the second structure 1100S in the first structure 1100F.

In the first structure 1100F, the decoder circuit 1110 and the page buffer 1120 may execute a control operation on at least one memory cell transistor selected from among the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connecting wire 1135 extending from the first structure 1100F to the second structure 1100S.

The controller 1200 may include a processor 1210, a NAND controller 1220, and a host interface 1230. According to another implementation, the electronic system 1000 may include a plurality of semiconductor devices 1100, and in this case, the controller 1200 may control the semiconductor devices 1100.

The processor 1210 may control an overall operation of the electronic system 1000 including the controller 1200. The processor 1210 may operate according to predetermined firmware and may access the semiconductor devices 1100 by controlling the NAND controller 1220. The NAND controller 1220 may include a NAND interface 1221 that processes communication with the semiconductor devices 1100. A control command for controlling the semiconductor device 1100, data to be recorded in the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When a control command is received from an external host through the host interface 1230, the processor 1210 may control the semiconductor devices 1100 in response to the control command.

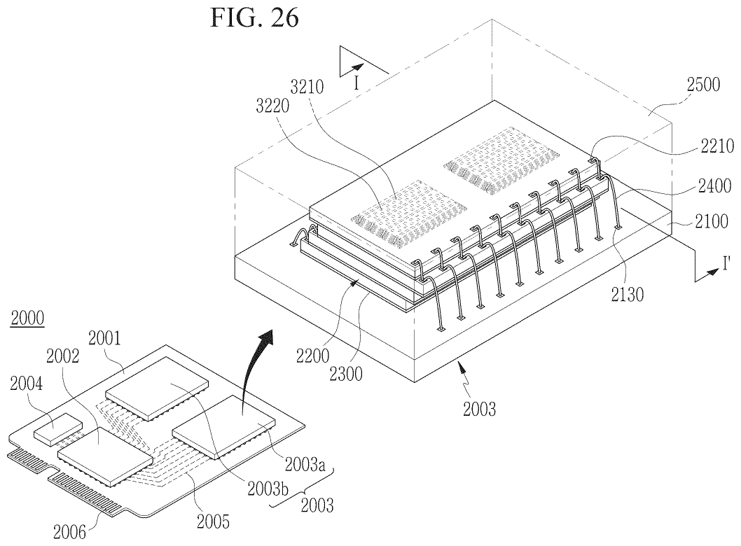

FIG. 26 illustrates a schematic perspective view showing an electronic system including a semiconductor device according to some implementations.

Referring to FIG. 26, an electronic system 2000 according to some implementations includes a main substrate 2001, a controller 2002 mounted on the main substrate 2001, one or more semiconductor packages 2003, and a DRAM 2004. The semiconductor package 2003 and the DRAM 2004 may be connected to the controller 2002 through a wire pattern 2005 positioned on the main substrate 2001.

The main substrate 2001 may include a connector 2006 including a plurality of pins coupled to an external host. A number and disposition of the pins in the connector 2006 may vary depending on a communication interface between the electronic system 2000 and the external host. In some implementations, the electronic system 2000 may communicate with the external host according to any one of interfaces such as a universal flash storage (USB), a peripheral component interconnect express (PCI-Express), a serial advanced technology attachment (SATA), M-Phy for universal flash storage (UFS), and the like. In some implementations, the electronic system 2000 may operate with power supplied from an external host through the connector 2006. The electronic system 2000 may further include a power management integrated circuit (PMIC) that distributes power supplied from the external host to the controller 2002 and semiconductor package 2003.

The controller 2002 may record data in the semiconductor package 2003, or may read data from the semiconductor package 2003, and may improve an operation speed of the electronic system 2000.

The DRAM 2004 may be a buffer memory for buffering a speed difference between the semiconductor package 2003, which is a data storage space, and an external host. The DRAM 2004 included in the electronic system 2000 may also operate as a kind of cache memory and may provide a space for temporarily storing data in the control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 on the package substrate 2100, an adhesive layer 2300 disposed on a lower surface of each semiconductor chip 2200, a connecting structure 2400 that electrically connects the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 25. Each semiconductor chip 2200 may include a gate stack structure 3210 and a channel structure 3220. The semiconductor chip 2200 may include the semiconductor device described with reference to FIG. 1 to FIG. 10.

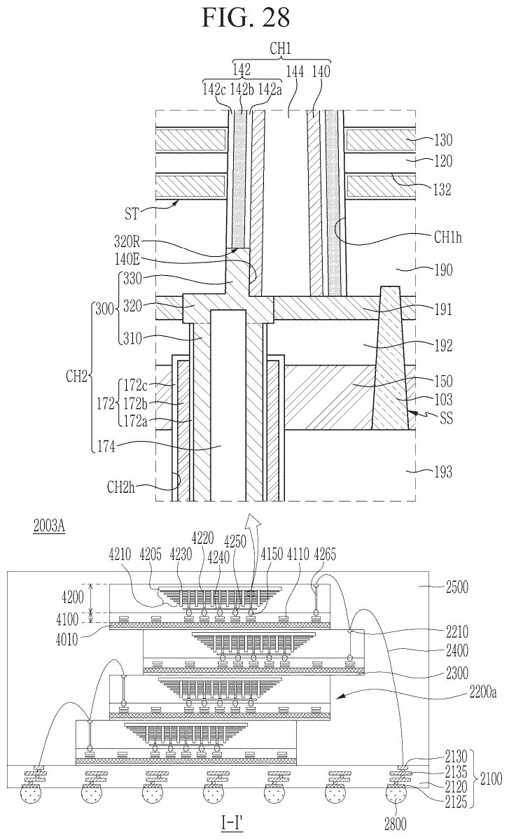

FIG. 27 and FIG. 28 illustrate schematic cross-sectional views showing semiconductor packages according to some implementations.

Referring to FIG. 27, in the semiconductor package 2003, the package substrate 2100 may be a printed circuit board. The package substrate 2100 may include a package substrate body 2120, a package upper pad 2130 positioned on an upper surface of the package substrate body 2120, a lower pad 2125 positioned on or exposed through the lower surface of the package substrate body 2120, and an inner wire 2135 that electrically connects the upper pad 2130 and the lower pad 2125 inside the package substrate body 2120. The upper pad 2130 may be electrically connected to the connecting structure 2400. The lower pad 2125 may be connected to the wire pattern 2005 of the main substrate 2010 of the electronic system 2000 through a conductive connector 2800 as illustrated in FIG. 29.

The semiconductor chip 2200 may each include a semiconductor substrate 3010, and a first structure 3100 and a second structure 3200 stacked in turn on the semiconductor substrate 3010. The first structure 3100 may include a peripheral circuit region including a peripheral wire 3110. The second structure 3200 may include a common source line 3205, a gate stack structure 3210 on the common source line 3205, a channel structure 3220 and a separating structure 3230 through the gate stack structure 3210, a bitline 3240 electrically connected to the channel structure 3220, and a gate connecting wire electrically connected to a word line WL (see FIG. 25) of the gate stack structure 3210.

In the semiconductor chip 2200 or semiconductor device according to the implementation, a contact area between the second channel layer 300 and the first channel structure CH1 may increase, and thus the first channel structure CH1 and the second channel structure CH2 may be stably connected.

Each of the semiconductor chips 2200 may include a through wire 3245 that is electrically connected to the peripheral wire 3110 of the first structure 3100 and extends into the second structure 3200. The through wire 3245 may extend through the gate stack structure 3210 and may be further positioned outside the gate stack structure 3210. Each semiconductor chip 2200 may further include an input/output connection wire 3265 electrically connected to the peripheral wire 3110 of the first structure 3100 and an input/output pad 2210 electrically connected to the input/output connecting wire 3265 extending into the second structure 3200.

In some implementations, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including a through silicon via (TSV).

Referring to FIG. 28, in a semiconductor package 2003A, each semiconductor chip 2200a may include a semiconductor substrate 4010, a first structure 4100 on the semiconductor substrate 4010, and a second structure 4200 bonded to a first structure 4100 by wafer bonding on the first structure 4100.

The first structure 4100 may include a peripheral circuit region including a peripheral wire 4110 and a first junction structure 4150. The second structure 4200 may include a common source line 4205, a gate stack structure 4210 between the common source line 4205 and the first structure 4100, a channel structure 4220 and a separating structure 4230 extending through the gate stack structure 4210, and a second junction structure 4250 electrically connected to the word line WL (see FIG. 25, hereinafter the same) of each of the channel structure 4220 and the gate stack structure 4210. For example, the second junction structure 4250 may be electrically connected to the channel structure 4220 and the word line WL through a bit line 4240 electrically connected to the channel structure 4220 and a gate connecting wire electrically connected to the word line WL, respectively. The first junction structure 4150 of the first structure 4100 and the second junction structure 4250 of the second structure 4200 may be bonded while contacting each other. A bonded portion of the first junction structure 4150 and the second junction structure 4250 may be formed of, e.g., copper (Cu).

In the semiconductor chip 2200a or semiconductor device according to the implementation, the contact area between the second channel layer 300 and the first channel structure CH1 may increase, and thus the first channel structure CH1 and the second channel structure CH2 may be stably connected.

Each of the semiconductor chips 2200a may further include an input/output pad 2210 and an input/output connecting wire 4265 under the input/output pad 2210. The input/output connecting wire 4265 may be electrically connected to a portion of the second junction structure 4250.

In an implementation, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including the through silicon via (TSV).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it is to be understood that the disclosure is not limited to the disclosed implementations, but, on the contrary, is intended to cover various modifications and equivalent dispositions included within the spirit and scope of the appended claims.

What is claimed is:

1. A semiconductor device comprising:
a substrate;
a stacked structure including a plurality of gate electrodes stacked on the substrate and spaced apart from each other;
a first channel structure including (i) a first channel layer extending through the stacked structure and extending along a direction and (ii) a first ferroelectric layer positioned between the first channel layer and the stacked structure;
an insulating pattern positioned on the stacked structure;
a selection gate electrode positioned on the insulating pattern; and
a second channel structure connected to the first channel structure through the selection gate electrode and the insulating pattern, the second channel structure including a second channel layer extending along the direction,
wherein the second channel layer includes:
a first portion extending through the selection gate electrode;
a second portion extending through the insulating pattern and contacting an upper surface of the first channel layer; and
a third portion protruding from a lower surface of the second portion and contacting an outer surface of the first channel layer.

2. The semiconductor device of claim 1, wherein
the third portion is positioned on the first ferroelectric layer.

3. The semiconductor device of claim 2, wherein
the second channel layer further includes:
a fourth portion protruding from a lower surface of the second portion and contacting an inner surface of the first channel layer.

4. The semiconductor device of claim 1, wherein
a thickness of the insulating pattern in the direction is greater than or equal to a width of the first ferroelectric layer in a radial direction from a center of the first channel structure.

5. The semiconductor device of claim 4, wherein
a thickness of the second portion in the direction is equal to a width of the third portion in the radial direction from the center of the first channel structure.

6. The semiconductor device of claim 1, wherein
at least a portion of the third portion does not overlap the second portion in the direction.

7. The semiconductor device of claim 1, wherein
at least a portion of the first channel structure overlaps the second channel structure in the direction.

8. The semiconductor device of claim 7, wherein
a first side portion of the first ferroelectric layer is in contact with the second channel layer, and a second side portion of the first ferroelectric layer is in contact with the insulating pattern.

9. The semiconductor device of claim 7, further comprising:
a cell region insulating layer positioned between the insulating pattern and the stacked structure and covering an upper surface of the stacked structure and a side surface of the first channel structure,
wherein a first side portion of the second portion overlaps the cell region insulating layer in the direction, and a second side portion of the second portion overlaps the first channel structure in the direction.

10. The semiconductor device of claim 1, wherein
a thickness of the selection gate electrode in the direction is greater than a thickness of each of the gate electrodes in the direction, and
the selection gate electrode includes a different material from a material of the gate electrodes.

11. The semiconductor device of claim 1, wherein
the second channel structure includes a second ferroelectric layer that surrounds the first portion of the second channel layer, and
the first portion overlaps the second portion in the direction.

12. The semiconductor device of claim 11, further comprising:
a second blocking layer positioned between the second ferroelectric layer and the selection gate electrode,
wherein the second blocking layer further extends between the second channel layer and the second portion.

13. The semiconductor device of claim 11, wherein
the first to third portions of the second channel layer include a same material.

14. A semiconductor device comprising:
a substrate;
a stacked structure including a plurality of gate electrodes stacked on the substrate and spaced apart from each other;
a first channel structure including a first channel layer extending through the stacked structure along a direction, and a first ferroelectric layer positioned between the first channel layer and the stacked structure;
an insulating pattern positioned on the stacked structure;
a selection gate electrode positioned on the insulating pattern; and
a second channel layer overlapping at least a portion of the first channel structure in the direction, and to include a second channel layer connected to the first channel structure through the selection gate electrode and the insulating pattern, and a second ferroelectric layer positioned between the second channel layer and the selection gate electrode, wherein the second channel layer further includes:
a first portion extending through the selection gate electrode;
a second portion extending through the insulating pattern to contact an upper surface of the first channel layer; and
a third portion positioned between the first ferroelectric layer and the second portion and to contact a side surface of the first channel layer.

15. The semiconductor device of claim 14, wherein
a thickness of the insulating pattern in the direction is greater than or equal to a width of the first ferroelectric layer in a radial direction from a center of the first channel structure.

16. The semiconductor device of claim 15, wherein
a thickness of the second portion in the direction is equal to a width of the third portion in the radial direction from the center of the first channel structure.

17. The semiconductor device of claim 14, wherein
a first side portion of the first ferroelectric layer is in contact with the channel layer, and a second side portion of the first ferroelectric layer is in contact with the insulating pattern.

18. The semiconductor device of claim 17, wherein
a portion of an upper surface of the first channel layer is in contact with the second channel layer, and a remaining portion of the upper surface of the first channel layer is in contact with the insulating pattern.

19. An electronic system comprising:
a main substrate;
a semiconductor device on the main substrate; and
a controller electrically connected to the semiconductor device on the main substrate,
wherein the semiconductor device includes:
a peripheral circuit region;
a cell region including an input/output connection wire electrically connected to the peripheral circuit region; and
an input/output pad electrically connected to the input/output connection wire extending into the cell region,
wherein the cell region includes:
a substrate;
a stacked structure including a plurality of gate electrodes stacked on the substrate and spaced apart from each other;
a first channel structure including a first channel layer extending through the stacked structure and extending along a direction, and a first ferroelectric layer positioned between the first channel layer and the stacked structure;
an insulating pattern positioned on the stacked structure;
a selection gate electrode positioned on the insulating pattern; and
a second channel structure connected to the first channel structure through the selection gate electrode and the insulating pattern and including a second channel layer extending along the direction,
wherein the second channel layer includes:
a first portion extending through the selection gate electrode;
a second portion extending through the insulating pattern to contact an upper surface of the first channel layer; and
a third portion protruding from a lower surface of the second portion and contacting a side surface of the first channel layer.

20. The electronic system of claim 19, wherein
the third portion is positioned on the first ferroelectric layer, and
at least a portion of the third portion overlaps the second portion in the direction, and a remaining portion of the second portion does not overlap the second portion in the direction.
